(19) United States
(12) Patent Application Publication
(10) Pub. No.: US 2009/0014795 A1
(43) Pub. Date: Jan. 15, 2009

(54) Substrate for field effect transistor, field effect transistor and method for production thereof

(76) Inventors: Risho Koh, Tokyo (JP); Katsuhiko Tanaka, Tokyo (JP); Shigeharu Yamagami, Tokyo (JP); Koichi Terashima, Tokyo (JP); Hitoshi Wakabayashi, Tokyo (JP); Kiyoshi Takeuchi, Tokyo (JP); Masayasu Tanaka, Tokyo (JP); Masahiro Nomura, Tokyo (JP); Koichi Takeda, Tokyo (JP)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/658,564

(22) PCT Filed: Jul. 14, 2005
(86) PCT No.: PCT/JP2005/013021

§ 371 Date: Jan. 25, 2007

(30) Foreign Application Priority Data
Jul. 29, 2004 (JP) 2004-221858

(51) Int. Cl. H01L 29/786; H01L 27/12; H01L 21/336

(52) U.S. Cl. 257/347; 257/506; 438/164; 257/E29.273; 257/E27.112; 257/E21.411

(57) ABSTRACT

A π gate FinFET structure having reduced variations in off-current and parasitic capacitance and a method for production thereof are provided. The structure of an element is improved so that an off-current suppressing capability can be exhibited more strongly. A field effect transistor, wherein a first insulating film and a semiconductor region are provided so as to protrude upward with respect to the flat surface of a base, the field effect transistor has a gate electrode, a gate insulating film and a source/drain region, and a channel is formed at least on the side surface of the semiconductor region, wherein that the first insulating film is provided on an etch stopper layer composed of a material having an etching rate lower than at least the lowermost layer of the first insulating film for etching under a predetermined condition.

### TECHNICAL FIELD

The present invention relates to a π gate type field effect transistor having reduced variations in off-current and parasitic capacitance.

### BACKGROUND OF THE INVENTION

For a conventional field effect transistor (hereinafter referred to as FinFET), a plan view is shown in FIG. 26, the section A-A′ of the plan view 26 is shown in FIG. 27(a), and the section B-B′ of the plan view 26 is shown in FIG. 27(b).

For example, as disclosed in Japanese Patent Laid-Open No. 64-8670 and Japanese Patent Laid Open No. 2002-118255, a buried insulating layer 2 is formed on a silicon substrate 1, a semiconductor layer 3 is protrusively provided on the upper part of the layer 2, a gate insulating film 4 is provided on the side surface of the semiconductor layer 3, and a gate electrode 5 is provided so as to contact the gate insulating film and straddle the semiconductor layer 3. A source/drain region 6 in which an impurity of a first conductivity type is introduced in a high concentration is formed on the semiconductor layer 3 in a portion of the semiconductor layer 3 which is not covered with the gate electrode. By applying a voltage to the gate electrode, a carrier is induced at a position opposite to the gate electrode in the semiconductor layer, and a channel of a first conductivity type is formed, and operates as a field effect transistor of a first conductivity type.

A field effect transistor where a cap insulating film 22 thicker than the gate insulating film is provided on the semiconductor layer 3 and a channel is formed on the side surface of the semiconductor layer is called a FinFET of double gate structure (hereinafter referred to as double gate FinFET), and a field effect transistor where no cap insulating film 22 is provided on the semiconductor layer 3, the gate insulating film 4 is provided on the semiconductor layer 3 and channels are formed on the side surface and the upper surface of the semiconductor layer is called a FinFET of trigate structure (hereinafter referred to as trigate FinFET).

As disclosed in John Tae Park, et al. “IEEE ELECTRON DEVICE LETTERS”, August, 2001, Vol. 22, No. 8, pages 405 to 406, one form of the FinFET in which the lower end of the gate electrode is extended downward by a depth Tdig below the lower end of the semiconductor layer 3 is called a FinFET of π gate structure (hereinafter referred to as π gate FinFET) because the gate electrode resembles π of Greek characters. This is shown in FIG. 27(a). This structure advantageously improves the steepness of ON-OFF transition (subthreshold characteristic) and suppresses an off-current, since a portion of the gate electrode extended downward from the lower end of the semiconductor layer has an effect of improving the controllability of the gate electrode for the electric potential of the lower part of the semiconductor layer.

In this specification, the height of the semiconductor layer 3 is called a fin height Hfin, and the width (width in lateral direction within the plane of the sheet in FIG. 27(a)) of the semiconductor layer 3 in a direction perpendicular to a direction extending between source/drain regions of the semiconductor layer 3 and parallel to the surface of a substrate (surface of a wafer on which a transistor is formed) is called a fin width Wfin.

(1) If the protrusion depth Tdig (FIG. 27(a)) of the gate electrode changes, the π gate FinFET, in its nature, produces a change in an off-current depending on Tdig. Tdig depends on how deeply the buried insulating layer 2 at a position in which the gate electrode 5 is formed is dug by etching prior to formation of the gate electrode 5, but variations in the etching rate are generally influenced by the loading effect and the state in an etching chamber, and is difficult to control precisely: Tdig thus varies, and resultantly, the off-current varies.

FIG. 28 shows the result of simulated influences of Tdig on the off-current in the π gate FinFET of FIGS. 27(a) and 27(b). It is apparent from FIG. 28 that the off-current changes depending on Tdig. Incidentally, the simulation of FIG. 27(a) was obtained by carrying out calculation for a trigate FinFET of n channels having a fin height Hfin of 20 nm, a fin width Wfin of 30 nm, a gate length of 40 nm and a gate oxide thickness of 2 nm, having no cap insulating film and having a gate insulating film having a thickness of 2 nm on a semiconductor layer. The channel doping was omitted and the work function of the gate electrode was set to middle gap (position of 0.6 eV toward the valence band side from the conduction band of n+ silicon). The drain current at a drain voltage 1.0 V and a gate voltage of 0 V was set to an off-current. The total thickness of the buried insulating was set to 130 nm.

(2) If Tdig varies, a parasitic capacitance between the lower end of the gate electrode and the substrate (C1 of FIG. 27(a)) also varies because the distance between the lower end of the gate electrode and the substrate changes. Parasitic capacitances in a portion of the gate electrode protruded below the lower end of the semiconductor layer and between source/drain regions also vary depending on Tdig.

If these parasitic capacitances vary, the operation speed of the transistor varies. Thus, a structure of a π gate FinFET having reduced variations in off-current and parasitic capacitance, and a method for production thereof are desired.

Aside from the problem of variations, it is desired to improve the structure of an element so that an off-current suppressing capability that is a feature of the π gate FinFET can be exhibited more strongly. In FIG. 28, for example, saturation is reached when Tdig is 15 nm or more and a level of reduction in off-current is about 1×10⁻¹¹ A, but an element structure capable of suppressing an off-current more significantly is desired.

### SUMMARY OF THE INVENTION

According to the present invention, the following field effect transistor and method for production thereof can be provided.

(1) A field effect transistor,

wherein a first insulating film composed of one or more layers and a semiconductor region provided on the first insulating film are provided so as to protrude upward with respect to the flat surface of a base, the field effect transistor comprises:

a gate electrode provided so as to straddle the semiconductor region and the first insulating film from the upper part of the semiconductor region;

a gate insulating film provided between the gate electrode and at least the side surface of the semiconductor region; and

a source/drain region provided in the semiconductor region so as to sandwich the gate electrode,

wherein a channel is formed at least on the side surface of the semiconductor region and the first insulating film is provided on an etch stopper layer composed of a material having an etching rate lower than at least the lowermost layer of

the first insulating film for etching under a predetermined condition.

(2) A field effect transistor comprising:

a protrusive semiconductor region;

a gate electrode provided so as to extend from the upper part of the semiconductor region to the position below the lower end of the semiconductor region;

a first insulating film provided below the semiconductor region so as to be sandwiched by the gate electrode;

a gate insulating film provided between the gate electrode and at least the side surface of the semiconductor region; and

a source/drain region provided in the semiconductor region so as to sandwich the gate electrode, and

wherein a channel is formed at least on the side surface of the semiconductor region and

the first insulating film is provided on an etch stopper layer composed of a material having an etching rate lower than at least the lowermost layer of the first insulating film for etching under a predetermined condition.

(3) The field effect transistor according to invention 1 or 2, wherein the field effect transistor comprises a layer composed of a material having a dielectric constant higher than that of SiO₂ below the semiconductor region.

(4) The field effect transistor according to any one of inventions 1 to 3, wherein the first insulating film comprises a layer composed of a material having a dielectric constant higher than that of SiO₂ at least on the etch stopper layer side.

(5) The field effect transistor according to invention 4, wherein the etch stopper layer comprises a SiO₂ layer at least on the first insulating film side.

(6) The field effect transistor according to invention 4 or 5, wherein the field effect transistor comprises a layer composed of a material having a dielectric constant higher than that of SiO₂ and a SiO₂ layer in descending order below the etch stopper layer.

(7) The field effect transistor according to invention 3, wherein the first insulating film comprises a SiO₂ layer on the etch stopper layer side.

(8) The field effect transistor according to invention 7, wherein the etch stopper layer comprises a layer composed of a material having a dielectric constant higher than that of SiO₂ at least on the first insulating film side.

(9) The field effect transistor according to invention 7 or 8, wherein the field effect transistor comprises a SiO₂ layer below the etch stopper layer.

(10) The field effect transistor according to any one of inventions 3 to 9, wherein the material having a dielectric constant higher than that of SiO₂ is Si₃N₄.

(11) The field effect transistor according to any one of inventions 1 to 10, wherein the field effect transistor comprises at least one cap insulating film between the upper surface of the semiconductor region and the gate electrode.

(12) The field effect transistor according to invention 11, wherein the cap insulating film comprises a layer composed of a material same as that of the etch stopper layer.

(13) The field effect transistor according to invention 12, wherein the uppermost layer of the cap insulating film is a layer composed of a material same as that of the etch stopper layer.

(14) The field effect transistor according to any one of inventions 1 to 13, wherein the thickness of the first insulating film is 40 nm or less.

(15) The field effect transistor according to any one of inventions 1 to 13, wherein the thickness of the first insulating film is 15 nm or less.

(16) The field effect transistor according to any one of inventions 1 to 13, wherein the thickness of the first insulating film is in a range of 7.5 nm to 40 nm.

(17) The field effect transistor according to any one of inventions 1 to 13, wherein the thickness of the first insulating film is equal to or less than 1.3 times as large as a width in a direction orthogonally crossing a direction of a channel current in the semiconductor region.

(18) The field effect transistor according to any one of inventions 1 to 13, wherein the thickness of the first insulating film is equal to or less than ½ times as large as a width in a direction orthogonally crossing a direction of a channel current in the semiconductor region.

(19) The field effect transistor according to any one of inventions 1 to 13, wherein the thickness of the first insulating film is in a range of ¼ to 1.3 times as large as a width in a direction orthogonally crossing a direction of a channel current in the semiconductor region.

(20) A field effect transistor comprising:

a SiO₂ region formed on a Si₃N₄ layer by etching under a condition bringing about an etching rate higher than Si₃N₄;

a semiconductor region provided on the SiO₂ region;

a gate electrode provided so as to straddle the semiconductor region and the SiO₂ region from the upper part of the semiconductor region;

a gate insulating film provided between the gate electrode and at least the side surface of the semiconductor region; and

a source/drain region provided in the semiconductor region so as to sandwich the gate electrode,

wherein a channel is formed on the side surface of the semiconductor region.

(21) The field effect transistor according to invention 20, wherein the field effect transistor comprises a cap insulating film between the upper surface of the semiconductor region and the gate electrode.

(22) The field effect transistor according to invention 21, wherein the field effect transistor comprises a Si₃N₄ layer as the cap insulating film.

(23) A field effect transistor comprising:

a Si₃N₄ region formed on a SiO₂ layer by etching under a condition bringing about an etching rate higher than SiO₂;

a semiconductor region provided on the Si₃N₄ region;

a gate electrode provided so as to straddle the semiconductor region and the Si₃N₄ region from the upper part of the semiconductor region;

a gate insulating film provided between the gate electrode and at least the side surface of the semiconductor region; and

a source/drain region provided in the semiconductor region so as to sandwich the gate electrode,

wherein a channel is formed on the side surface of the semiconductor region.

(24) The field effect transistor according to invention 23, wherein the field effect transistor comprises a Si₃N₄ layer and a SiO₂ layer in descending order below the SiO₂ layer.

(25) The field effect transistor according to invention 23 or 24, wherein the field effect transistor comprises a SiO₂ layer as a cap insulating film between the upper surface of the semiconductor region and the gate electrode.

(26) The field effect transistor according to invention 25, further comprising a Si₃N₄ layer as the cap insulating film below the SiO₂ layer.

(27) The field effect transistor according to any one of inventions 1 to 26, wherein the etching is reactive ion etching.

(28) The field effect transistor according to any one of inventions 1 to 19, wherein the width in a direction orthogonally crossing a channel current in the first insulating film is smaller than a width in a direction orthogonally crossing a channel current in the semiconductor region.

(29) The field effect transistor according to any one of inventions 1 to 28, wherein a plurality of semiconductor regions protruding upward from the surface of the base are arranged so that the directions of channel currents passing through the insides of the semiconductor regions are mutually parallel.

(30) A substrate for a field effect transistor comprising a semiconductor layer and layers having SiO₂ layers and Si₃N₄ layers laminated alternately below the semiconductor layer.

(31) A substrate for a field effect transistor comprising a semiconductor layer, a Si₃N₄ layer and a SiO₂ layer in descending order.

(32) A substrate for a field effect transistor comprising a semiconductor layer, a SiO₂ layer, a Si₃N₄ layer and a SiO₂ layer in descending order.

(33) A substrate for a field effect transistor comprising a semiconductor layer, a Si₃N₄ layer, a SiO₂ layer, a Si₃N₄ layer and a SiO₂ layer in descending order.

(34) A substrate for a field effect transistor comprising in descending order a semiconductor layer, a first insulating film layer and an etch stopper layer composed of a material having an etching rate lower than that of the first insulating film layer for etching under a predetermined condition.

(35) The substrate for a field effect transistor according to invention 34, wherein the etching is reactive ion etching.

(36) The substrate for a field effect transistor according to invention 34 or 35, wherein the thickness of the first insulating film layer is 30 nm or less.

(37) The substrate for a field effect transistor according to invention 34 or 35, wherein the thickness of the first insulating film layer is 15 nm or less.

(38) The substrate for a field effect transistor according to invention 34 or 35, wherein the thickness of the first insulating film layer is in a range of 7.5 nm to 30 nm.

(39) The substrate for a field effect transistor according to invention 38, wherein the first insulating film layer is a SiO₂ layer.

(40) The substrate for a field effect transistor according to any one of inventions 30 to 39, wherein the semiconductor layer is a silicon layer.

(41) The substrate for a field effect transistor according to any one of inventions 30 to 39, wherein the semiconductor layer is a monocrystalline silicon layer.

(42) A method for production of a field effect transistor in which at least one first insulating film and a semiconductor region provided on the first insulating film are provided so as to protrude upward with respect to the flat surface of a base, the field effect transistor has a gate electrode provided so as to straddle the first insulating film and the semiconductor region from the upper part of the semiconductor region, and the field effect transistor in which a channel is formed at least on the side surface of the semiconductor region,

comprising the steps of:

(a) etching a substrate having at least a semiconductor layer, a first insulating film layer consisting of one or more layers and an etch stopper layer in descending order, and forming a semiconductor region protruding on the first insulating film layer; and

(b) etching a portion of the first insulating film layer other than the portion provided with the semiconductor region until the etching reaches the etch stopper layer under a condition such that the etching rate of at least the lowermost layer of the first insulating film layer is higher than the etching rate of the etch stopper layer, and providing below the semiconductor region the first insulating film protruding upward from the etch stopper layer.

(43) The method for production of a field effect transistor according to invention 42, further comprising the steps of:

forming a gate insulating film on the side surface of the semiconductor region;

forming a gate electrode by depositing a gate electrode material and patterning the gate electrode material deposition film; and

introducing an impurity on both sides of the semiconductor region sandwiching the gate electrode to form a source/drain region.

(44) The method for production of a field effect transistor according to invention 43, wherein the step of forming the gate electrode comprises a step of providing a gate side wall.

(45) The method for production of a field effect transistor according to any one of inventions 42 to 44, wherein in the step (b) of providing the first insulating film, etching is carried out under a condition such that the etching rate of the lowermost layer of the first insulating film layer is equal to or greater than twice as large as the etching rate of the etch stopper layer.

(46) The method for production of a field effect transistor according to any one of inventions 42 to 44, wherein in the step (b) of providing the first insulating film, etching is carried out under a condition such that the etching rate of the lowermost layer of the first insulating film layer is equal to or greater than 5 times as large as the etching rate of the etch stopper layer.

(47) The method for production of a field effect transistor according to invention 44, wherein the step of providing the gate side wall are steps of depositing a gate side wall material on the entire surface, and then carrying out etch-back under a condition such that the etching rate of the gate side wall material is higher than the etching rate of the etch stopper layer.

(48) The method for production of a field effect transistor according to any one of inventions 42 to 47, wherein in the step (b) of providing the first insulating film, the etching is reactive ion etching.

(49) The method for production of a field effect transistor according to any one of inventions 42 to 48, wherein in the step (a) of forming the semiconductor region, a plurality of semiconductor regions are arranged so that the directions of channel currents passing through the semiconductor regions are mutually parallel.

Furthermore, according to the present invention, the following field effect transistor and method for production thereof can be provided.

(50) The field effect transistor according to invention 4 or 5, wherein the first insulating film further comprises a SiO₂ layer or a layer containing silicon, nitrogen and oxygen on the semiconductor region side.

(51) The field effect transistor according to invention 7 or 8, wherein the field effect transistor comprises a SiO₂ layer and a layer composed of a material having a dielectric constant higher than that of SiO₂ in descending order below the etch stopper layer.

(52) The field effect transistor according to invention 20, wherein the field effect transistor comprises a SiO₂ layer below the Si₃N₄ layer.

(53) The field effect transistor according to invention 20, wherein the field effect transistor comprises a SiO₂ layer and a Si₃N₄ layer in descending order below the Si₃N₄ layer.

(54) The field effect transistor according to invention 22, further comprising a SiO₂ layer as the cap insulating film below the Si₃N₄ layer,

(55) The field effect transistor according to invention 29, wherein an independent source/drain regions and gate electrodes are provided on each of the plurality of semiconductor regions.

(56) The field effect transistor according to invention 29, wherein the field effect transistor further comprises a coupling region protruding upward from the etch stopper layer, extending in a direction orthogonally crossing the direction of the channel current and sandwiching and coupling the plurality of semiconductor regions,

source/drain regions provided in the semiconductor regions are electrically common-connected via the semiconductor region included in the coupling region, and

the gate electrode is formed so as to straddle the plurality of semiconductor regions coupled by the coupling region.

Since Tdig can be defined by the thickness of au upper buried insulating film 31, variations in Tdig decrease. Given that the original amount of variations in Tdig is Tdig1, the amount of variations Tdig2 in this process decreases to (Tdig1×etching rate of etch stopper layer 32/etching rate of upper buried insulating film 31). Thus, variations in off-current and variations in parasitic capacitance are reduced.

Since in the structure of the present invention, the off-current is suppressed as compared to the conventional technique, Tdig can be set to be smaller as compared to the conventional technique. Compared to the value of Tdig at which the dependency on Tdig of the off-current value is reduced in the conventional technique, Tdig at which the dependency of Tdig is stabilized is smaller in the present invention, and therefore when the set value of Tdig is set to be in a range where the dependency on Tdig of the off-current is small (for further stabilizing the characteristics although the amount of variations in Tdig is originally small in the present invention), the set value of Tdig can also be reduced as compared to the conventional technique.

If Tdig is small, there is an advantage that a burden on the process is reduced and in addition, parasitic capacitances between the protruding gate electrode and the substrate and between the protruding gate electrode and the source/drain decrease.

By increasing the dielectric constant of at least a layer of buried insulating films (upper buried insulating film, etch stopper layer, lower buried insulating film, etc.), the electrostatic capacity of the side surface or the lower surface of the gate electrode protruding below the semiconductor layer and the lower part of the semiconductor layer (lower region of the semiconductor layer) increases, so that the controllability of the gate electrode for the electric potential of the lower part of the semiconductor layer is improved and the off current is reduced.

### BRIEF DESCRIPTION OF THE DRAWINGS

FIGS. 1(a) and 1(b) are sectional views for explaining the first embodiment;

FIGS. 2(a), 2(b) and 2(c) are sectional views for explaining the first embodiment;

FIGS. 3(a), 3(b) and 3(c) are sectional views for explaining the first embodiment;

FIGS. 4(a), 4(b) and 4(c) are sectional views for explaining the first embodiment;

FIGS. 5(a) and 5(b) are sectional views for explaining the first embodiment;

FIG. 6 is a plan view for explaining the first embodiment;

FIG. 7 is a drawing for explaining the effect of the invention;

FIGS. 8(a) and 8(b) are sectional views for explaining the second embodiment;

FIGS. 9(a), 9(b) and 9(c) are sectional views for explaining the second embodiment;

FIGS. 10(a), 10(b) and 10(c) are sectional views for explaining the second embodiment;

FIGS. 11(a), 11(b) and 11(c) are sectional views for explaining the second embodiment;

FIGS. 12(a) and 12(b) are sectional views for explaining the second embodiment;

FIG. 13 is a plan view for explaining the second embodiment;

FIG. 14 is a drawing for explaining the effect of the invention;

FIGS. 15(a) and 15(b) are sectional views for explaining the third embodiment;

FIGS. 16(a), 16(b) and 16(c) are sectional views for explaining the third embodiment;

FIGS. 17(a), 17(b) and 17(c) are sectional views for explaining the third embodiment;

FIGS. 18(a), 18(b) and 18(c) are sectional views for explaining the third embodiment;

FIGS. 19(a) and 19(b) are sectional views for explaining the third embodiment;

FIGS. 20(a) and 20(b) are plan views for explaining a preferred embodiment of the present invention;

FIGS. 21(a), 21(b) and 21(c) are sectional views for explaining the preferred embodiment of the present invention;

FIGS. 22(a) and 22(b) are sectional views for explaining the preferred embodiment of the present invention;

FIGS. 23(a) and 23(b) are sectional views for explaining the preferred embodiment of the present invention;

FIGS. 24(a), 24(b) and 24(c) are sectional views for explaining the preferred embodiment of the present invention;

FIG. 25 is a sectional view for explaining the preferred embodiment of the present invention;

FIG. 26 is a plan view for explaining a conventional technique;

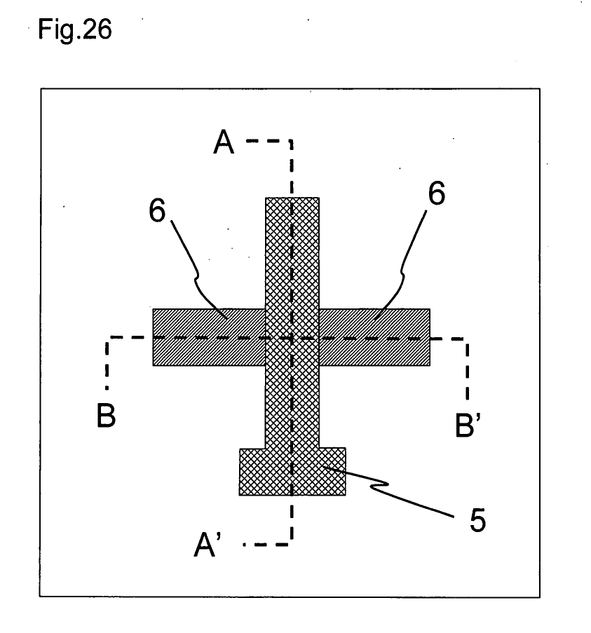

FIGS. 27(a) and 27(b) are sectional views for explaining the conventional technique;

FIG. 28 is an explanatory view of a problem in the conventional technique; and

FIG. 29 is a view for explaining a relationship between the etching rate and the flow rate of O₂.

### DETAILED DESCRIPTION OF THE INVENTION

A FinFET of the present invention is characteristic in that (1) the FinFET has a π gate structure and (2) a material used for at least the lowermost layer of a first insulating film has an etching rate higher than that of a material forming an etch stopper layer for etching of the first insulating film under a predetermined condition.

### First Embodiment

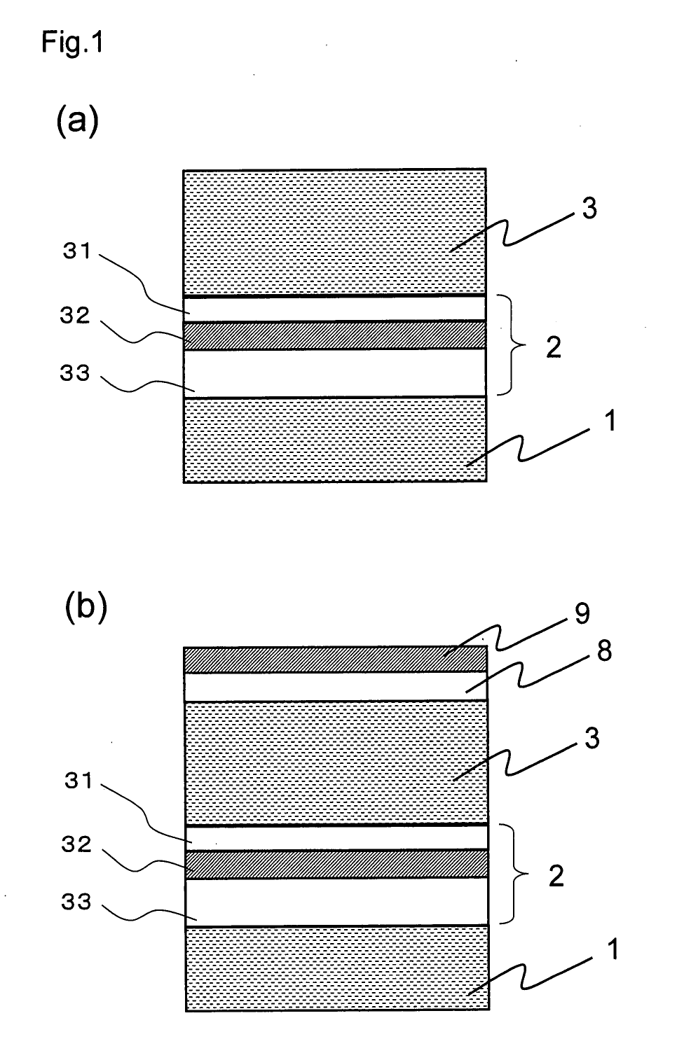

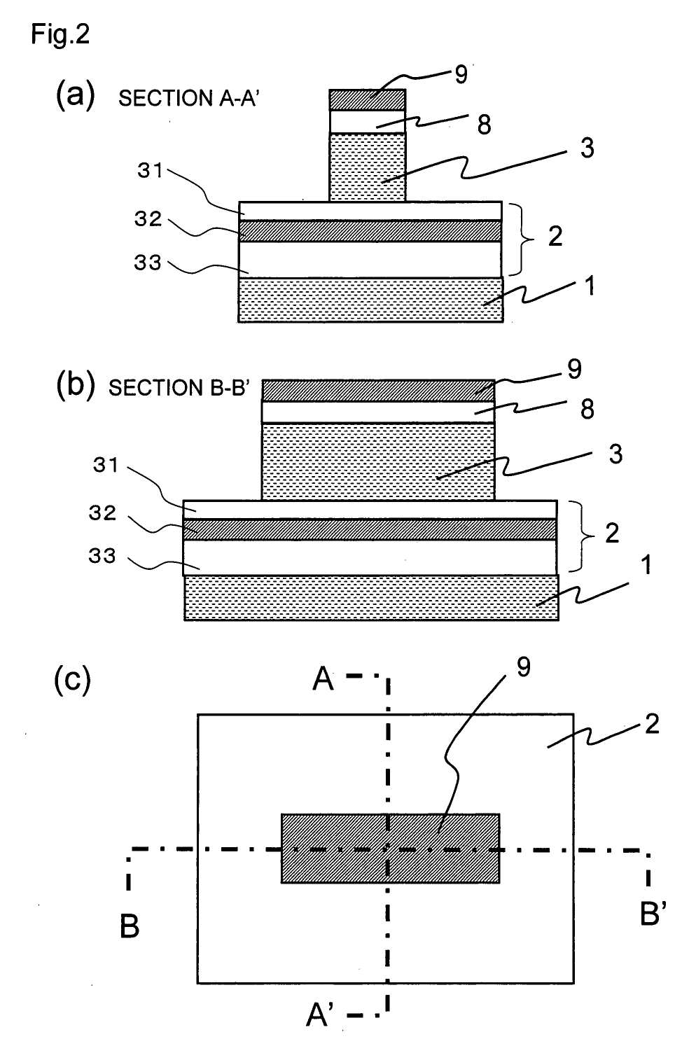

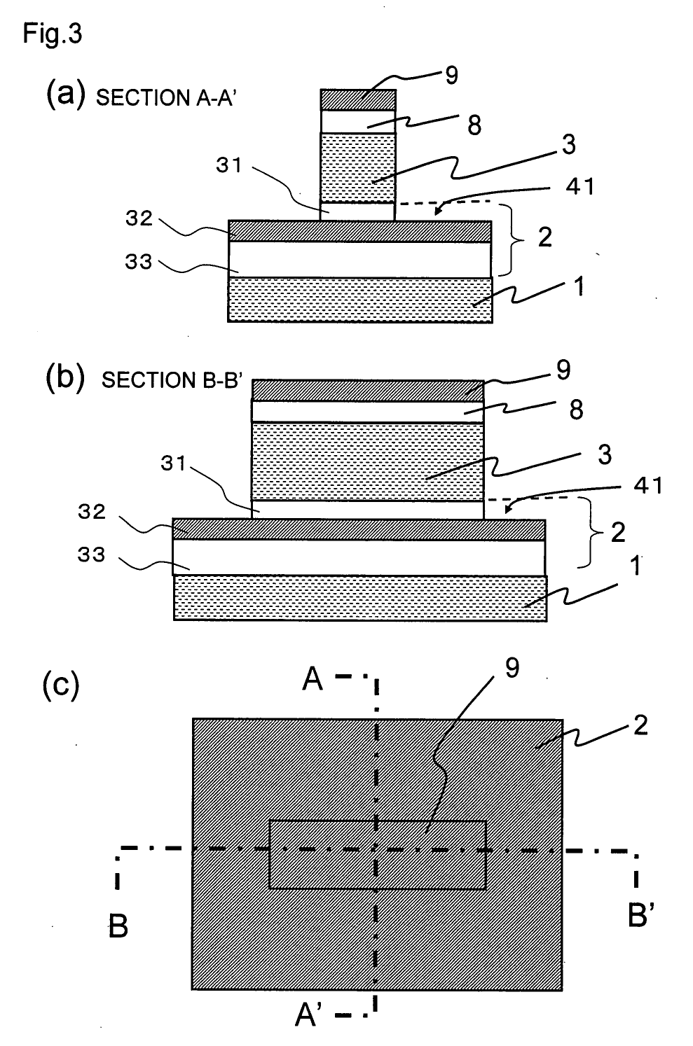

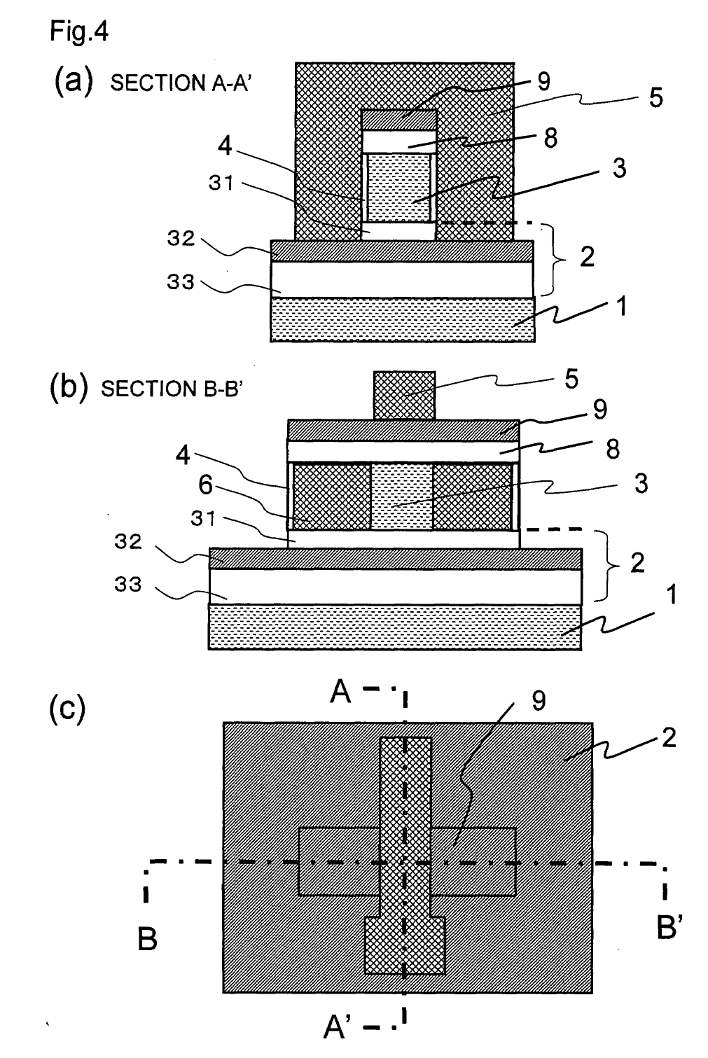

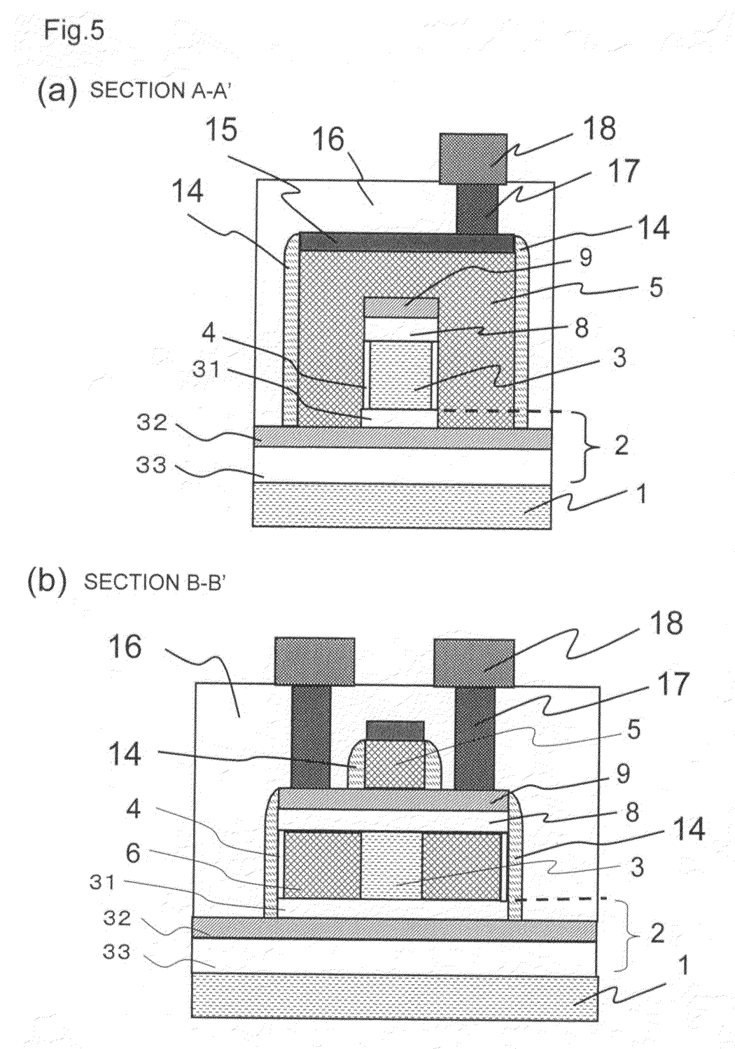

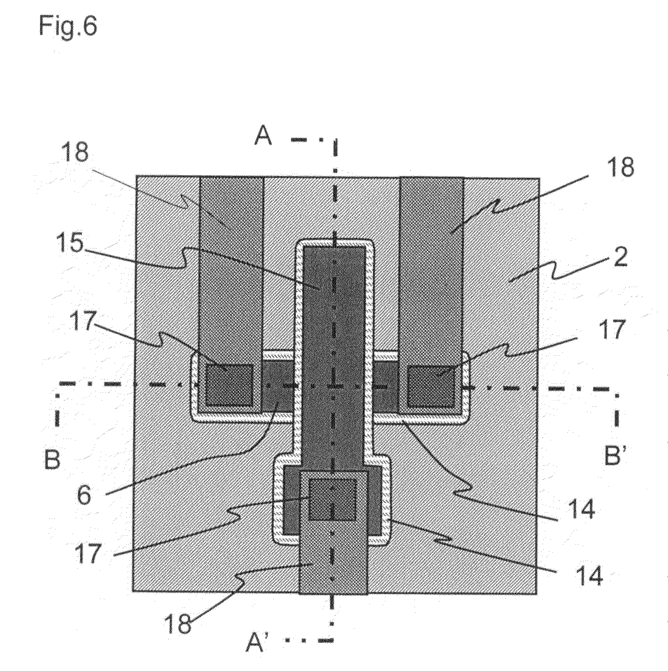

FIG. 1(a), FIG. 2(a), FIG. 3(a), FIG. 4(a) and FIG. 5(a) describe sections in section A-A′ of FIG. 1(c), FIG. 2(c), FIG. 3(c), FIG. 4(c) and FIG. 6, respectively, in the order of steps, and FIG. 1(b), FIG. 2(b), FIG. 3(b), FIG. 4(b) and FIG. 5(b) describe sections in section B-B′ of FIG. 1(c), FIG. 2(c), FIG. 3(c), FIG. 4(c) and FIG. 6, respectively, in the order of steps.

First, an SOI substrate having a semiconductor layer 3 laminated on a support substrate 1 via a buried insulating layer 2 is prepared. It is to be noted that the buried insulating layer 2 has a structure in which a lower buried insulating film 33, an etch stopper layer 32 and au upper buried insulating film (first insulating film) 31 are laminated in this order from the support substrate side (FIG. 1(a)).

A cap insulating film is provided on the upper part (upper surface) of the semiconductor layer 3 of this SOI substrate. FIG. 1(b) shows a case where the cap insulating film consists of a first cap insulating film 8 and a second cap insulating film 9. The material of the support substrate 1 is generally silicon, but may be a material other than silicon. The support substrate may be a semiconductor or an insulator.

The material of the upper buried insulating film 31 and the material of the etch stopper layer 32 are selected so that the upper buried insulating film 31 can be selectively etched with respect to the etch stopper layer 32 (namely, for the material of the etch stopper layer, a material having an etching rate lower than that of the first insulating film is selected for etching under a predetermined condition that is used in etching of the upper buried insulating film 31). Typically, the etching rate of the etch stopper layer 32 is preferably equal to or less than ½, more preferably equal to or less than ⅕, of the etching rate of the upper buried insulating film 31. An example of a combination of typical materials is a combination of SiO₂ as the upper buried insulating film 31 and Si₃N₄ as the etch stopper layer 32. In this case, for both the upper buried insulating film 31 and etch stopper layer 32, the atomic composition ratio may be changed to a certain extent from SiO₂ and Si₃N₄, respectively, within the boundary of maintaining the aforementioned condition of the etching rate. For both the upper buried insulating film 31 and etch stopper layer 32, other atoms may be mixed in SiO₂ and Si₃N₄, respectively, in a certain ratio, within the boundary of maintaining the aforementioned condition of the etching rate. For the etch stopper layer 32, a high dielectric material such as hafnium silicate, hafnium oxide, tantalum oxide or alumina may be used.

The material of the cap insulating film is not specifically limited. It is preferable that particularly when a multilayer cap insulating film is used, a layer of a material same as that of the etch stopper layer 32 is used for the uppermost layer, or a layer of a material same as that of the etch stopper layer 32 is inserted into at least the interior of the uppermost layer, and when a single-layer cap insulating film is used, the material of the cap insulating film is composed of a material same as that of the etch stopper layer 32, since in a step of etching the upper buried insulating film 31 to form a region (buried insulating film digging portion 41) where the gate electrode is extended to the lower part of the semiconductor layer (semiconductor region), which will be described later, the layer of a material same as that of the etch stopper layer 32 has resistance to etching, and therefore the cap insulating film is hard to be etched. (Incidentally, in this specification, the resistance to etching means that the etching rate is lower than that of a main material to be etched as a target of intended etching in the relevant etching step. The etching rate of a material having etching resistance is typically equal to or less than ½ of a main material to be etched as a target of intended etching.) If a layer of a material same as that of the etch stopper layer 32 is not inserted, the cap insulating film may be made so thick that it is not lost by etching. Instead of using a material same as that of the etch stopper layer 32 for the aforementioned regions constituting the cap insulating film, a material having a low etching rate for etching for forming the buried insulating film digging portion 41 and being different from the material of the etch stopper layer 32 may be used for the aforementioned regions constituting the cap insulating film.

When the upper buried insulating film 31 is SiO₂ and the etch stopper layer 32 is Si₃N₄, typically a first cap insulating film 8 may be formed with SiO₂ and a second cap insulating film 9 may be formed with Si₃N₄. The first cap insulating film 8 and the second cap insulating film 9 may be both deposited by a firm formation technique such as a CVD method. The first cap insulating film 8 may be a thermally oxidized film.

The total thickness of the buried insulating layer 2 is not specifically limited, but it is normally about 50 nm to 1 μm.

The lower buried insulating film 33 is a layer inserted below the etch stopper layer 32 for which Si₃N₄ having a high dielectric constant is typically used, for the purpose of securing adhesiveness between the support substrate 1 and the buried insulating film and reducing a capacitance between the source/drain region and the substrate, and the lower buried insulating film 33 is typically composed of SiO₂. Its thickness is normally about 50 nm to 1 μm. However, if necessary adhesiveness is secured between the etch stopper layer 32 and the support substrate 1 and the buried insulating film even though the lower buried insulating film 33 does not exist, or if the etch stopper layer 32 is thick or the like and a capacitance between the source/drain region and the substrate is suppressed to a necessary level even though the lower buried insulating film 33 does not exist, it is not necessary to provide the lower buried insulating film 33.

One example of a method for production of the field effect transistor of the first embodiment will be described below.

By a normal lithography step and etching step, the semiconductor layer 3 and the cap insulating films (8 and 9) are patterned to form an element region (FIGS. 2(a), 2(b) and 2(c)).

The upper buried insulating film 31 is etched by an etching step such as RIE in regions on opposite sides of the semiconductor layer with the etch stopper layer 32 as a stopper to form the buried insulating layer digging portion 41. An etching condition in etching the upper buried insulating film 31 is selected so that the etching rate of the upper buried insulating film 31 is higher than the etching rate for the etch stopper layer 32 (FIGS. 3(a), 3(b) and 3(c)).

By this step, the upper buried insulating film 31 is removed and the etch stopper layer is exposed in regions on opposite sides of the semiconductor layer.

Incidentally, here, a resist pattern used in processing in FIGS. 2(a), 2(b) and 2(c) is removed, followed by etching the upper buried insulating film 31 with the second cap insulating film 9 as a mask, but the resist pattern may be left rather than being removed after processing in FIGS. 2(a), 2(b) and 2(c), and the upper buried insulating film 31 may be etched with a resist as a mask.

Since a gate electrode material is buried in the buried insulating layer digging portion 41 in a subsequent step, the depth of the buried insulating layer digging portion 41 is equal to the depth Tdig of a gate electrode extension portion. The etch stopper layer 32 is not etched, or otherwise only slightly etched, and therefore in the present invention, Tdig can be defined by the thickness of the upper buried insulating film and Tdig can be inhibited from being varied due to variations in etching.

For providing explanations in detail, given that the maximum value of variations in Tdig caused by variations in etching when the present invention is not used is Tdig1, the maximum value Tdig2 of variations in Tdig in this process decreases to (Tdig1×etching rate of etch stopper layer 32/etching rate of upper buried insulating film 31). When the etch stopper layer 32 is composed of Si₃N₄ and the upper buried insulating film 31 is composed of SiO₂, the etching rate in the RIE process of SiO₂ can be normally made equal to or greater than twice as high as the etching rate of Si₃N₄, and therefore Tdig 2 can be normally made equal to or less than ½ of Tdig1.

The gate insulating film 4 is formed on the side surface of the semiconductor layer 3 in a manner similar to a normal MOSFET formation process, a gate electrode material is deposited and patterned to form the gate electrode 5, and an impurity of high concentration (n type dopant for an n channel transistor and p type dopant for a p channel transistor. Normally, the impurity is introduced so that the impurity concentration is 1×10¹⁹ cm⁻³ or greater) is introduced by ion implantation or the like with the gate electrode as a mask to form the source/drain region 6 to complete a transistor (FIGS. 4(a), 4(b) and 4(c)).

At this time, prior to formation of the gate insulating film, a step of temporarily thermally oxidizing the side surface of a silicon layer (semiconductor region) exposed by etching to form a sacrificial oxide film and removing the sacrificial oxide film by diluted hydrofluoric acid may be carried out to remove an etching damage layer on the side surface of the semiconductor layer 3. Channel ion implantation may be carried out after forming the sacrificial oxide film.

A gate side wall 14 composed of an insulating film, a silicide region 15 composed of cobalt silicide, nickel silicide or the like, an interlayer insulating film 16 composed of SiO₂, and a contact 17 and a wiring 18 composed of a metal are formed in a manner similar to a normal MOSFET fabrication process (FIGS. 5(a) and 5(b) and FIG. 6).

In the FinFET of the present invention formed by the production method described above, typically the upper buried insulating film 31 is further formed below the semiconductor layer and the etch stopper layer 32 is further provided below the upper buried insulating film 31 as shown in FIGS. 5(a) and 5(b) and FIG. 6. In a section of a region covered with the gate electrode, which is vertical to a channel direction (section corresponding to the section of FIG. 5(a)), the gate electrode 5 is provided on the opposite side surfaces of the upper buried insulating film 31. The upper buried insulating film 31 does not exist below the gate electrode existing on the side of the upper buried insulating film 31 where the gate electrode extends below the lower end of the semiconductor layer. On opposite sides of the upper buried insulating film 31, the lower end of the gate electrode contacts the etch stopper layer 32 (However, for a reason associated with a step of forming a thin oxide film on the etch stopper layer 32 composed of Si₃N₄ at the time of gate oxidization, or the like, a very thin layer, i.e. a very thin SiO₂ layer in this case, may be inserted between the lower end of the gate electrode and the etch stopper layer 32. Such a very thin film is not essential in the action of the present invention, and therefore in this case, this specification describes that the lower end of the gate electrode contacts the etch stopper layer 32). Incidentally, the width of the semiconductor layer 3 is almost equal to that of the upper buried insulating film 31 (however, there may be a slight difference for some reason associated with a step of gate oxidization, sacrificial oxidization, wet etching, cleaning or the like).

In the typical example in which the upper buried insulating film 31 is composed of SiO₂ and the etch stopper layer 32 is composed of Si₃N₄, in a section of a region covered with the gate electrode, which is vertical to a channel direction (section corresponding to the section of FIG. 5(a)), the upper buried insulating film 31 composed of SiO₂ is provided below the semiconductor layer 3 so as to be sandwiched on opposite sides by the gate electrode, and in a region where the gate electrode extends below the lower end of the semiconductor layer on opposite sides of the upper buried insulating film 31, the upper buried insulating film 31 composed of SiO₂ is not present below the gate electrode, and the lower end of the gate electrode contacts the etch stopper layer 32 composed of Si₃N₄ on opposite sides of the upper buried insulating film 31.

Therefore, in the present invention, Tdig is almost equal to the thickness of the upper buried insulating film 31 (for a reason associated with a step, the upper surface of the etch stopper layer 32 may be slightly lower in height than a position at which the semiconductor layer is provided, on opposite sides of the position at which the semiconductor layer is provided).

In the present invention, Tdig can be defined by the thickness of the upper buried insulating film 31, and therefore variations in Tdig are reduced. Given that the original amount of variations in Tdig is Tdig1, the amount of variations Tdig2 in this process decreases to (Tdig1×etching rate of etch stopper layer 32/etching rate of upper buried insulating film 31). Thus, variations in off-current and variations in parasitic capacitance are reduced.

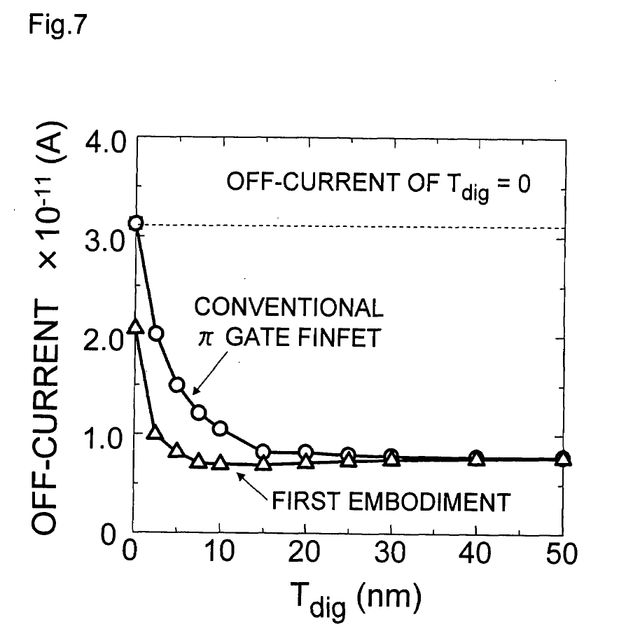

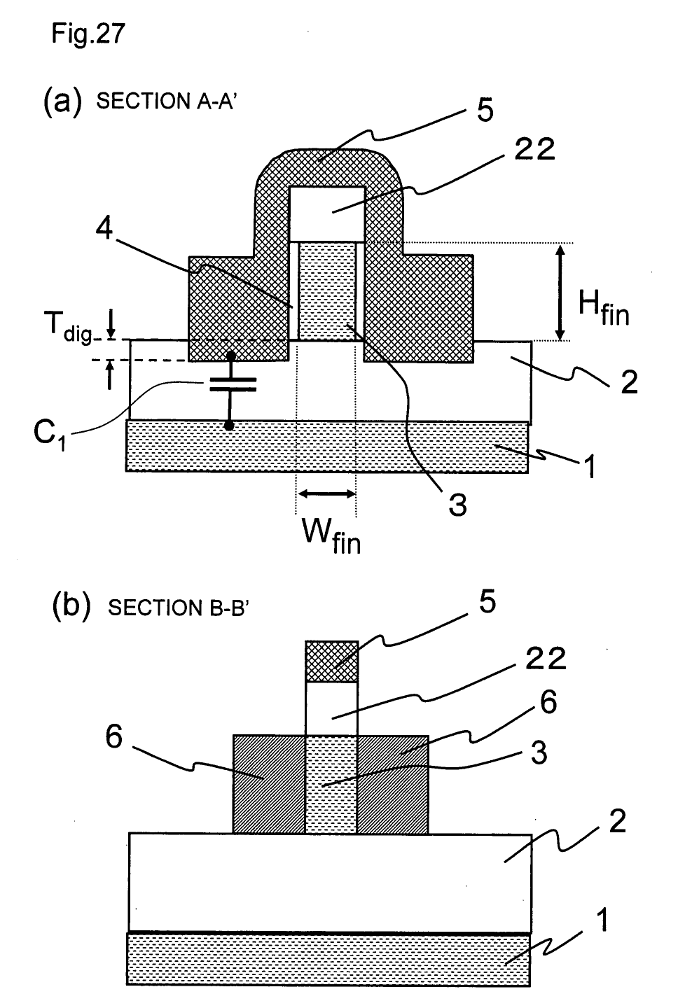

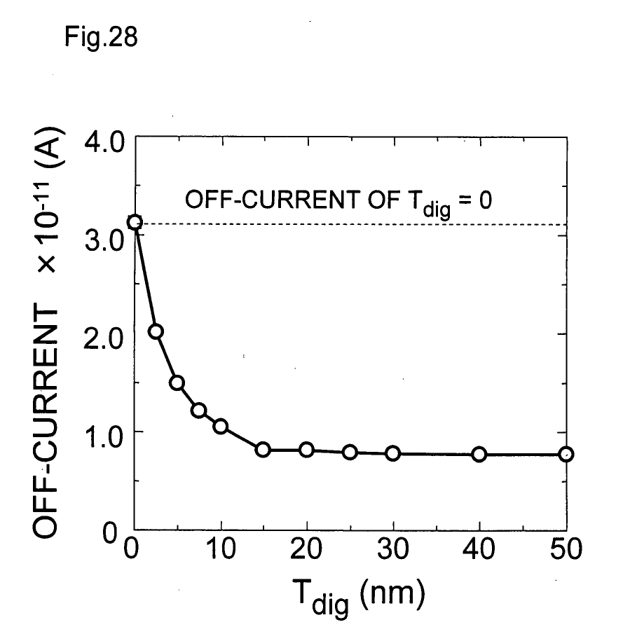

For the typical example in which the upper buried insulating film is composed of SiO₂ and the etch stopper layer is composed of Si₃N₄, the result of calculating the off-current in the same manner as in FIG. 27(a) is shown in FIG. 7. In the simulation, the total thickness of the buried insulating films was set to 130 nm and the lower buried insulating film was omitted. The off-current shown as a conventional technique in the figure represents the result of FIG. 28.

It is apparent from FIG. 7 that the present invention has the following second effect in addition to the aforementioned first effect of enabling variations in Tdig to be suppressed. In the structure of the present invention, the off-current is suppressed particularly in a region where Tdig is 20 nm or less as compared to the conventional technique, and therefore in the present invention, Tdig can be set to be smaller as compared to the conventional technique. In the conventional technique, the dependency on Tdig of the off-current is reduced at Tdig>20 nm, but in the present invention, the dependency is stabilized at Tdig=7.5 nm or greater, and therefore when the set value of Tdig is set to be in a range where the dependency on Tdig of the off-current is small (for further stabilizing the characteristics although the amount of variations in Tdig is originally small in the present invention), the set value of Tdig can also be reduced as compared to the conventional technique.

If Tdig is small, there is an advantage that a burden on the process is reduced and in addition, parasitic capacitances between the protruding gate electrode, and the substrate and between the protruding gate electrode and the source/drain decrease.

Incidentally, the second effect in the aforementioned typical example is brought about by using a material (Si₃N₄) having a dielectric constant higher than the upper buried insulating film (SiO₂) for the etch stopper layer so that electrostatic coupling between the gate electrode and the semiconductor layer through the etch stopper layer increases and controllability of the gate electrode for an electric potential distribution in the lower part of the semiconductor layer increases. When a material other than Si₃N₄ is used for the etch stopper layer, this effect is also obtained if the dielectric constant of the etch stopper layer is higher than the dielectric constant of the upper buried insulating film (typically the dielectric constant of SiO₂).

Incidentally, the first purpose of inserting the lower buried insulating film 33 is to reduce a parasitic capacitance between the gate electrode and the substrate and a parasitic capacitance between the source/drain region and the substrate. From a viewpoint of this purpose, the lower buried insulating film 33 is preferably formed with a material, typically SiO₂, having a dielectric constant lower than that of the etch stopper layer 32 formed with Si₃N₄. The second purpose is to use as an adhesion surface the lower buried insulating film 33 formed with SiO₂ having good adhesiveness when forming an SOI substrate by a bonding process. Incidentally, the adhesion surface may be any of the upper boundary surface and the lower boundary surface of the lower buried insulating film 33 and the interior of the lower buried insulating film 33.

As a material of each of the upper buried insulating film and the etch stopper layer, a combination of SiO₂ as the upper buried insulating film and Si₃N₄ as the etch stopper layer may be presented as a typical combination, and the result of calculating characteristics for this typical transistor has been shown in the first embodiment, but other materials may be combined such that the etch stopper layer has resistance to etching of the upper buried insulating film may be used.

### Second Embodiment

The second embodiment is one example of the first embodiment, and has a form in which the buried insulating layer 2 has a double-layer structure of the upper buried insulating film (the first insulating film) 31 (Si₃N₄) and the etch stopper layer 32 (SiO₂).

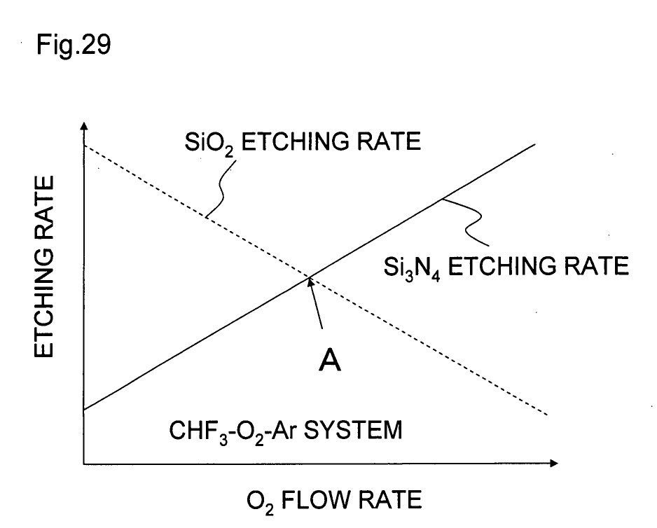

Incidentally, at the end of the first embodiment, an example of using a SiO₂ layer as the upper buried insulating film 31 and a Si₃N₄ layer as the etch stopper layer 32 has been presented as a typical example, but in the second embodiment, materials used for the upper buried insulating film 31 and the etch stopper layer 32 are inverted compared to the aforementioned typical example, and in the step of processing the upper buried insulating film 31 by etching, a condition with which the magnitude relation of the etching rate of Si₃N₄ and SiO₂ is inverted compared to the aforementioned typical example is used. For example, in etching by RIE using a mixed gas of CHF₃, O₂ and Ar, the etching rate of SiO₂ is higher than the etching rate of Si₃N₄ when the O₂ flow rate ratio in the mixed gas is close to 0. So, when the O₂ flow rate ratio is gradually increased from a value close to 0, the etching rate of Si₃N₄ increases and the etching rate of SiO₂ decreases (FIG. 29). The etching rate of SiO₂ and Si₃N₄ become equal to each other at point A in the figure, and when the O₂ flow rate ratio is increased from point A, the magnitude relation of etching rate of SiO₂ and Si₃N₄ is inverted.

For example, when the FinFET of the aforementioned typical example of the first embodiment is produced, etching by RIE may be carried out at an oxygen flow rate ratio lower than point A. In this case, typically an O₂ flow rate ratio at which the etching rate of SiO₂ is equal to or more than double the etching rate of Si₃N₄ is used. When the FinFET of the second embodiment is produced, etching by RIE may be carried out at an O₂ flow rate ratio higher than point A. In this case, typically an O₂ flow rate ratio at which the etching rate of Si₃N₄ is equal to or more than double the etching rate of SiO₂ is used.

By changing other conditions for etching of RIE, i.e. the type of etching gas, the temperature of the interior of an etching chamber, the pressure, the RF power and the like, the magnitude relation of the etching rate for the first insulating film and the etch stopper layer may be adjusted so that the etching rate for the first insulating film is higher than the etching rate for the etch stopper layer.

Thus, for same two materials, the magnitude relation of the etching rate for both materials is not uniquely determined according to the material, but is determined according to the type of material and the etching method and conditions, and therefore in this embodiment and each embodiment of the present invention, the etching method and conditions are selected so as to meet the requirement of the present invention that the etch stopper layer should have etching resistance in the step of etching the upper buried insulating film 31.

Incidentally, in the second embodiment, the etching rate of Si₃N₄ is set to be higher than the etching rate of SiO₂. Especially preferably, Si₃N₄ is equal to or greater than twice as high as the etching rate of SiO₂.

In the second embodiment, it is not necessary to provide the lower buried insulating film below the etch stopper layer 32, since the dielectric constant of the etch stopper layer 32 is low and SiO₂ that is excellent in adhesiveness is used in fabrication of an SOI substrate by a bonding step.

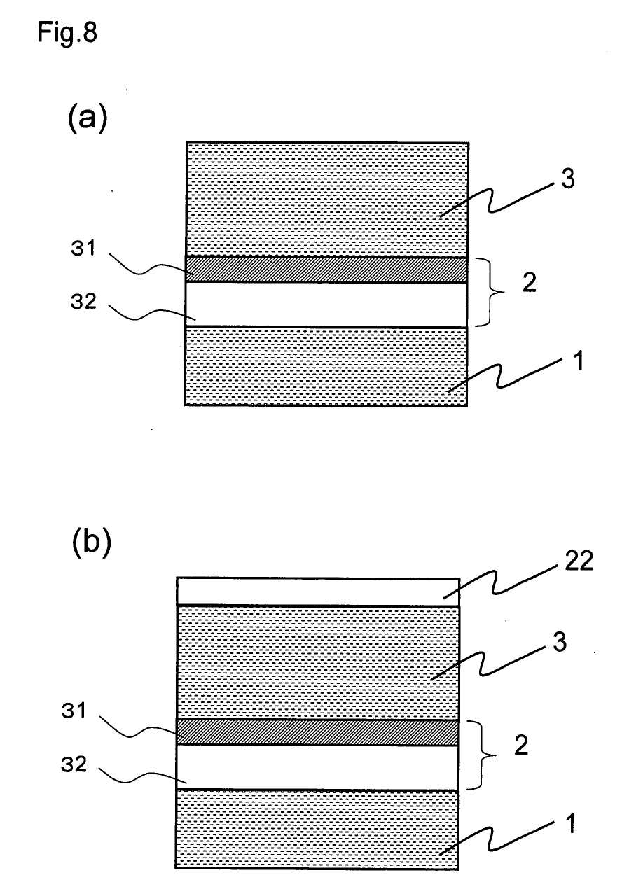

The upper part of the cap insulating film 22 is composed of a material same as that of the etch stopper layer 32 (cap insulating film 22 is composed of SiO₂), and if a multilayer cap insulating film is used, it is preferable that a layer of a material same as that of the etch stopper layer 32 is used for the uppermost layer of the film, or a layer of a material same as that of the etch stopper layer 32 is inserted into the multilayer cap insulating film. In the drawings of FIGS. 8(a) and 8(b) and subsequent drawings, a case where a single-layer SiO₂ film is applied as the cap insulating film 22 is shown.

In this case, for both the upper buried insulating film 31 and etch stopper layer 32, the atomic composition ratio may be changed to a certain extent from SiO₂ and Si₃N₄, respectively, and other elements may be mixed to a certain extent within the boundary of maintaining the aforementioned condition of the etching rate.

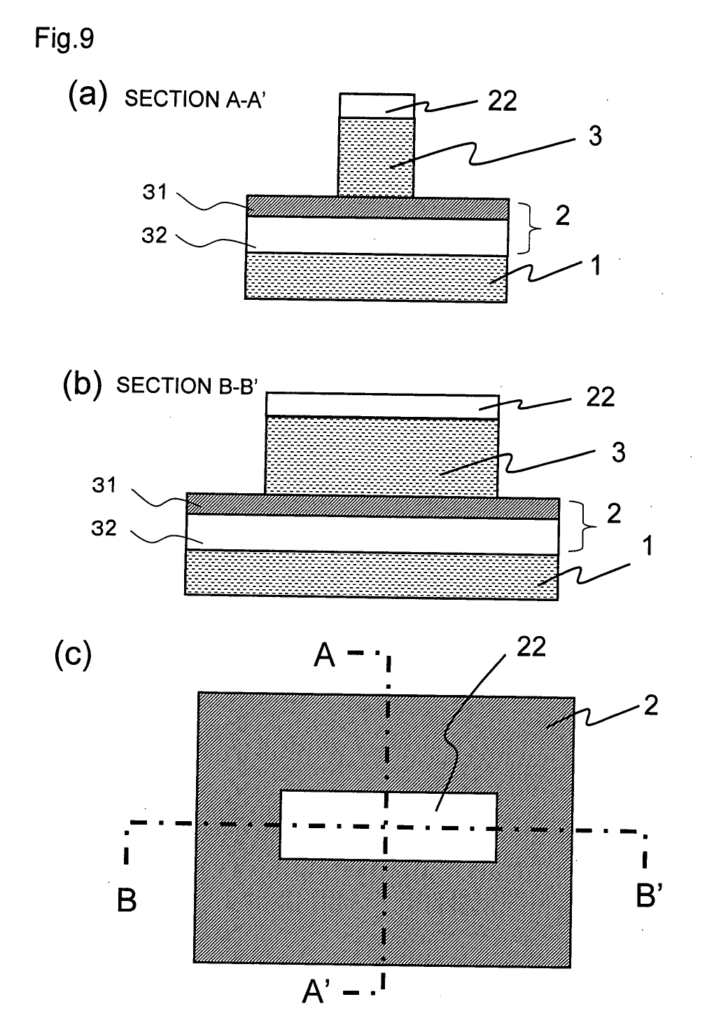

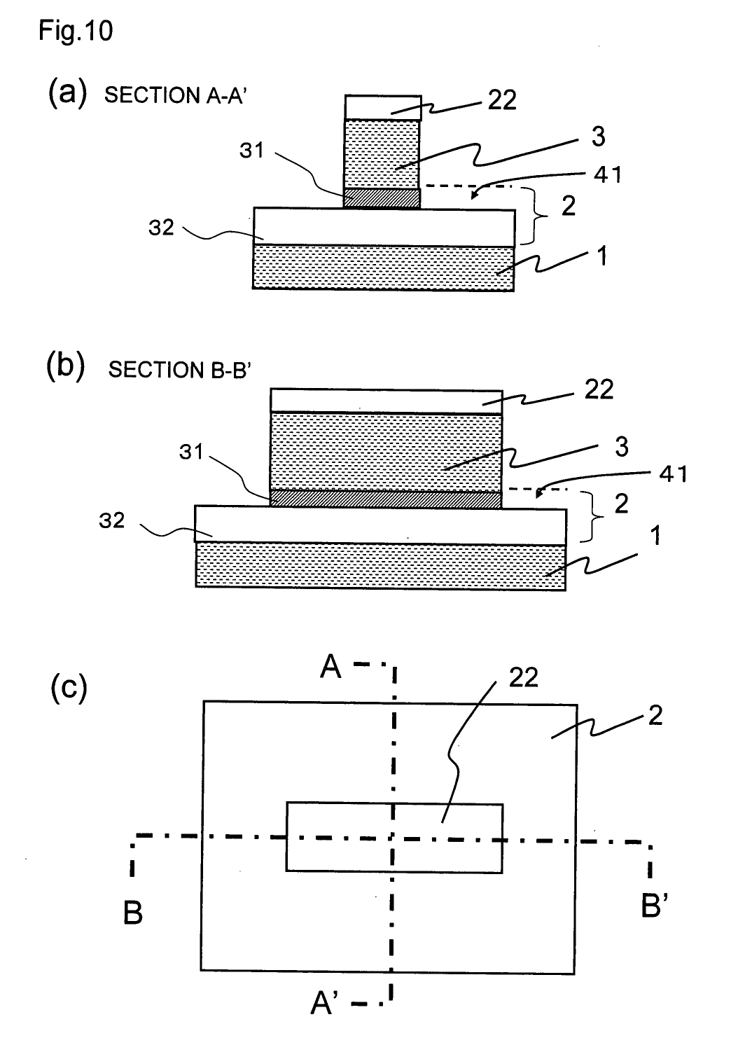

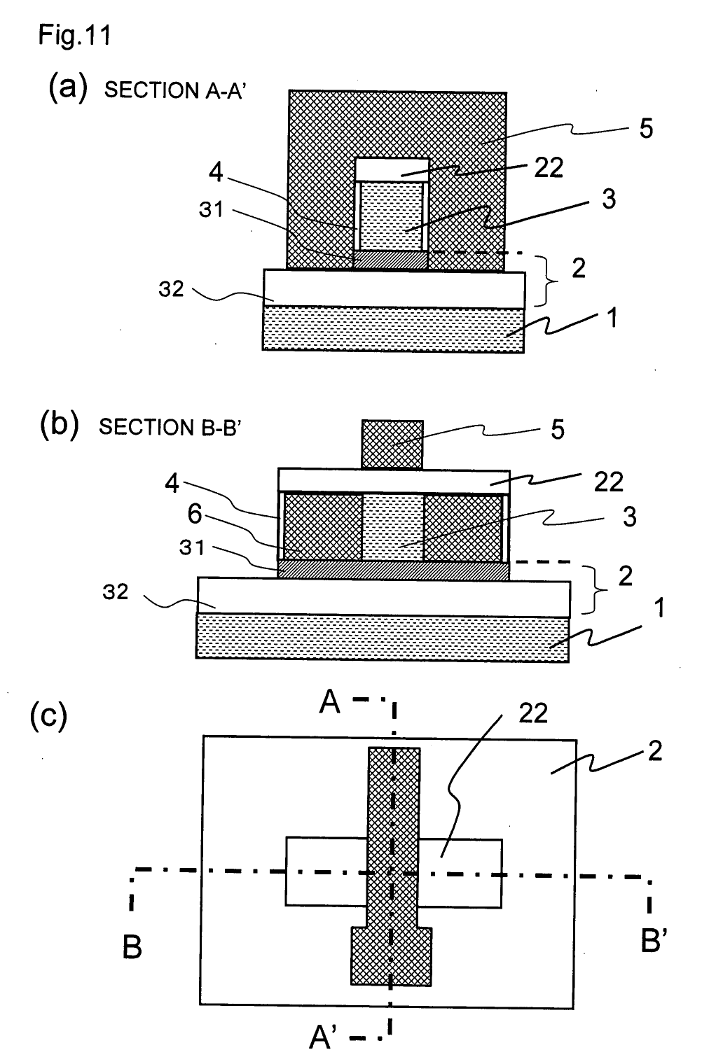

Incidentally, FIGS. 8(a) and 8(b), FIGS. 9(a), 9(b) and 9(c), FIGS. 10(a), 10(b) and 10(c), FIGS. 11(a), 11(b) and 11(c), FIGS. 12(a) and 12(b) and FIG. 13 are drawings corresponding to FIGS. 1(a) and 1(b), FIGS. 2(a), 2(b) and 2(c), FIGS. 3(a), 3(b) and 3(c), FIGS. 4(a), 4(b) and 4(c), FIGS. 5(a) and 5(b) and FIG. 6 in first embodiment, respectively.

In this embodiment, when the upper buried insulating film 31 (Si₃N₄) is etched with the etch stopper layer 32 (SiO₂) as a stopper to form the buried insulating layer digging portion 41, a condition is selected so that the etching rate of the upper buried insulating film 31 (Si₃N₄) is higher than the etching ratio for the etch stopper layer 32, and therefore the etch stopper layer 32 is not etched, or otherwise only slightly etched. Tdig is determined by the amount of etching of the buried insulating layer, but in this case, Tdig can be defined by the thickness of the upper buried insulating film, and therefore variations in Tdig decrease. The etching rate of the upper buried insulating film 31 (Si₃N₄) can be made higher than the etching rate for the etch stopper layer 32 by, for example, increasing the oxygen flow rate in RIE.

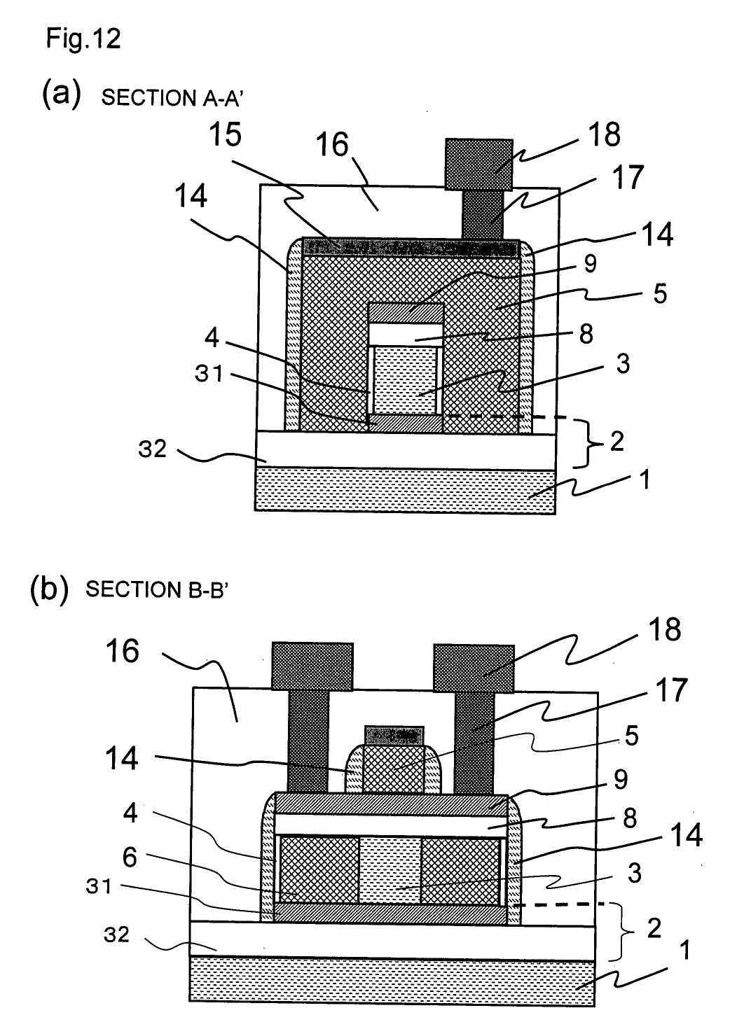

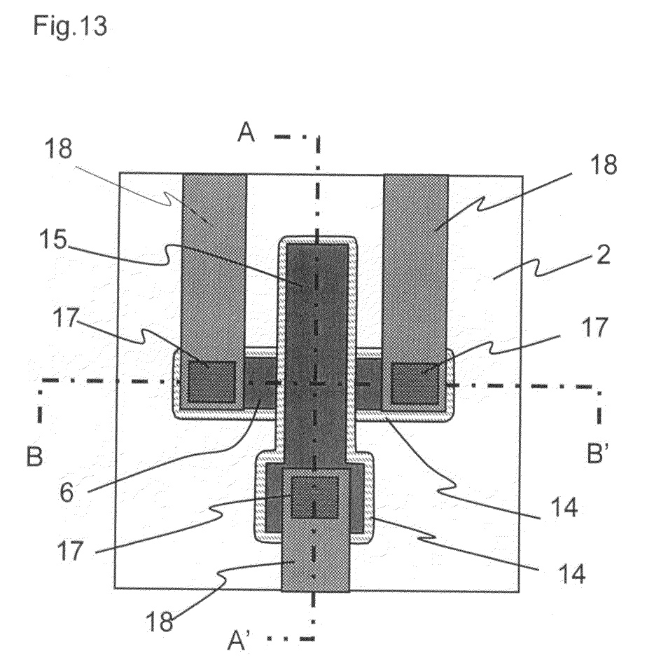

In this embodiment in which the upper buried insulating film 31 is composed of Si₃N₄ and the etch stopper layer 32 is composed of SiO₂ as shown in FIGS. 12(a) and 12(b) and FIG. 13, in a section of a region covered with the gate electrode, which is vertical to a channel direction (section corresponding to the section of FIG. 5(a)), the upper buried insulating film 31 composed of Si₃N₄ is provided so as to be further sandwiched on opposite sides by the gate electrode below the semiconductor layer 3. The upper buried insulating film 31 composed of Si₃N₄ is not present below a region where the gate electrode extends below the lower end of the semiconductor layer on opposite sides of the upper buried insulating film 31 and the lower end of the gate electrode contacts the etch stopper layer 32 composed of SiO₂ on opposite sides of the upper buried insulating film 31.

Incidentally, for a reason associated with a step of forming a thin oxide film on opposite sides of the upper buried insulating film 31 composed of Si₃N₄ at the time of gate oxidization, or the like, a very thin layer, i.e. a very thin SiO₂ layer in this case, may be inserted between the side surface of the gate electrode and the upper buried insulating film 31. Such a very thin film is not essential in the action of the present invention, and therefore in this case, this specification describes that the lower end of the gate electrode contacts the side surface of the upper buried insulating film 31.

In the second embodiment, given that the maximum value of variations in Tdig resulting from variations in etching in the conventional technique is Tdig1, the maximum value Tdig 2 of variations in Tdig in this process decreases to (Tdig1×etching rate of etch stopper layer 32/etching rate of upper buried insulating film 31) as described in the first embodiment.

Process conditions of other steps are same as those described in the first embodiment except that the configurations of the buried insulating layer 2 and the cap insulating film 22 are different from those in the first embodiment.

In the second embodiment, Tdig can be defined by the thickness of the upper buried insulating film, and therefore variations in Tdig decrease as described in the first embodiment. Given that the amount of variations in original Tdig is Tdig1, the amount of variations Tdig2 in this process decreases to (Tdig1×etching rate of etch stopper layer 32/etching rate of upper buried insulating film 31). Thus, variations in off-current and variations in parasitic capacitance are reduced.

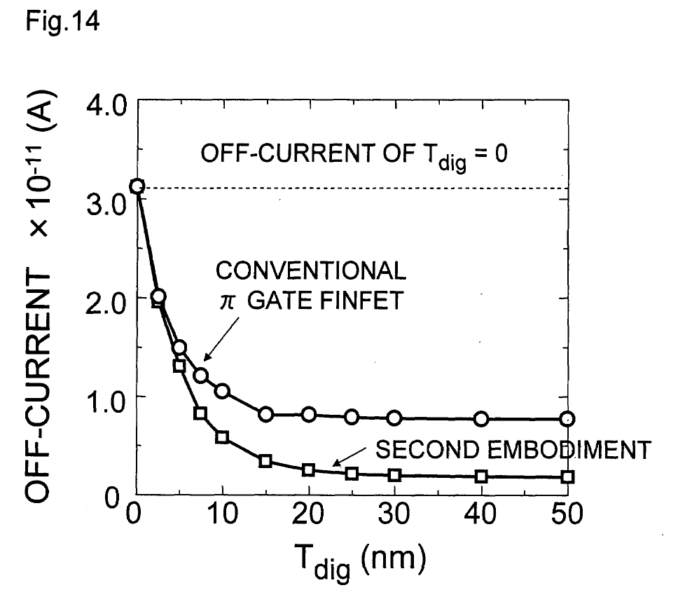

The result of simulation of the off-current when the upper buried insulating film 31 is composed of Si₃N₄, the etch stopper layer 32 is composed of SiO₂, and Tdig is changed is shown in FIG. 14. Element structures other than the structure of the buried insulating layer, and calculation conditions are same as those in FIG. 7. The off-current shown as the conventional technique in the figure is a result of FIG. 28.

The second effect of the second embodiment is that the off-current is small as compared to a normal π gate FinFET if Tdig is the same.

The off-current in a region where the effect is saturated (Tdig>30 nm) decreases to about ⅓ of a normal π gate FinFET. In this embodiment, since the upper buried insulating film has a high dielectric constant because it is composed of Si₃N₄, and an electrostatic capacitance between the gate electrode protruding to the lower part and the lower part of the semiconductor layer is large, controllability of the gate electrode for an electric potential in the lower part of the semiconductor layer is improved.

The second effect is also obtained when a material other than Si₃N₄ having a dielectric constant higher than SiO₂ is used for the upper layer buried insulating layer.

The second effect is an effect obtained due to the fact that the dielectric constant of the upper buried insulating film sandwiched by the gate electrode protruding below the lower end of the semiconductor layer is higher than that of SiO₂ constituting the buried insulating film in the conventional FinFET.

### Third Embodiment

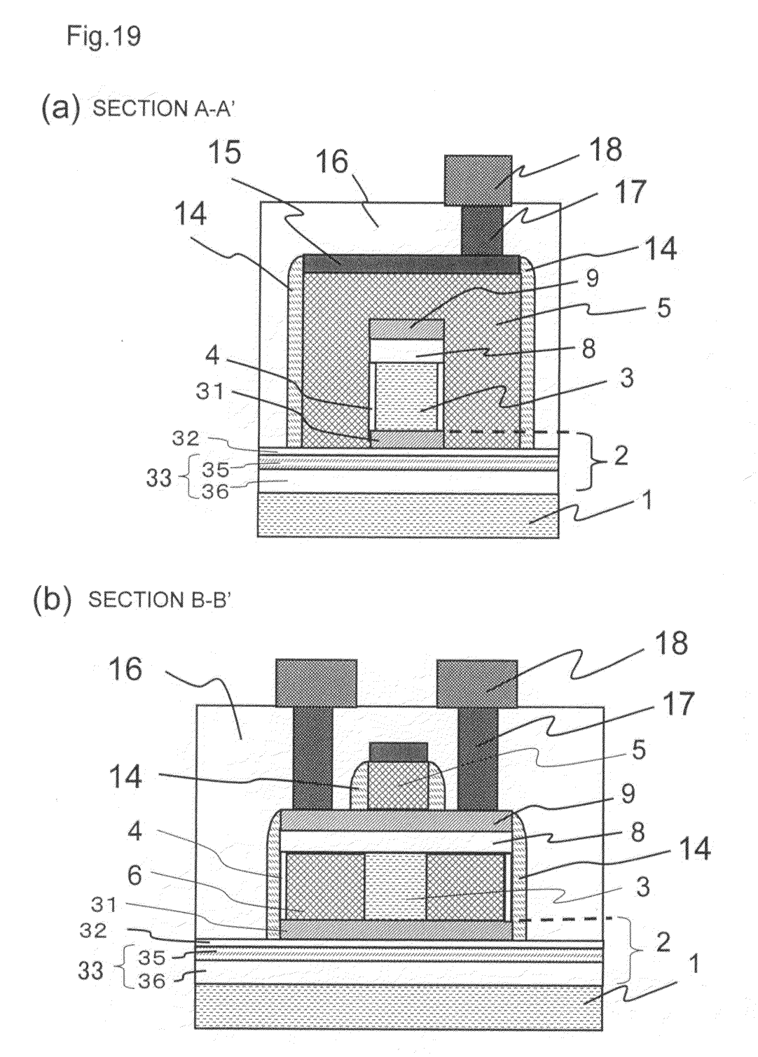

As shown in FIGS. 19(a) and 19(b), in the third embodiment, a layer of a buried high dielectric film 35 composed of a material having a dielectric constant higher than that of a material constituting the upper buried insulating film 31 or a material constituting the etch stopper layer 32 is provided in the lower buried insulating film 33 in the first embodiment. The buried high dielectric film 35 has an effect of increasing an electrostatic capacitance between the lower part of the gate electrode and the lower part of the semiconductor layer, thereby improving controllability of an electric potential in the lower region of the semiconductor layer by the gate electrode and suppressing the off-current. If SiO₂ is used as a material constituting the upper buried insulating film 31 or a material constituting the etch stopper layer 32, the high dielectric film 35 is typically composed of Si₃N₄,

Typical examples of the third embodiment include a case where the lower buried insulating film 33 is added below the etch stopper layer 32, and the lower buried insulating film 33 is composed of two layers: the buried high dielectric film 35 (typically Si₃N₄, typical thickness: 10 nm to 50 nm) in the upper part and a lower buried insulating film 36 composed of SiO₂ in the lower part, with respect to the configuration of the second embodiment. The buried high dielectric film 35 has an effect of increasing an electrostatic capacitance between the lower part of the gate electrode and the lower part of the semiconductor layer, improving controllability of an electric potential in the lower region of the semiconductor layer by the gate electrode, and suppressing the off-current more strongly as compared to the second embodiment.

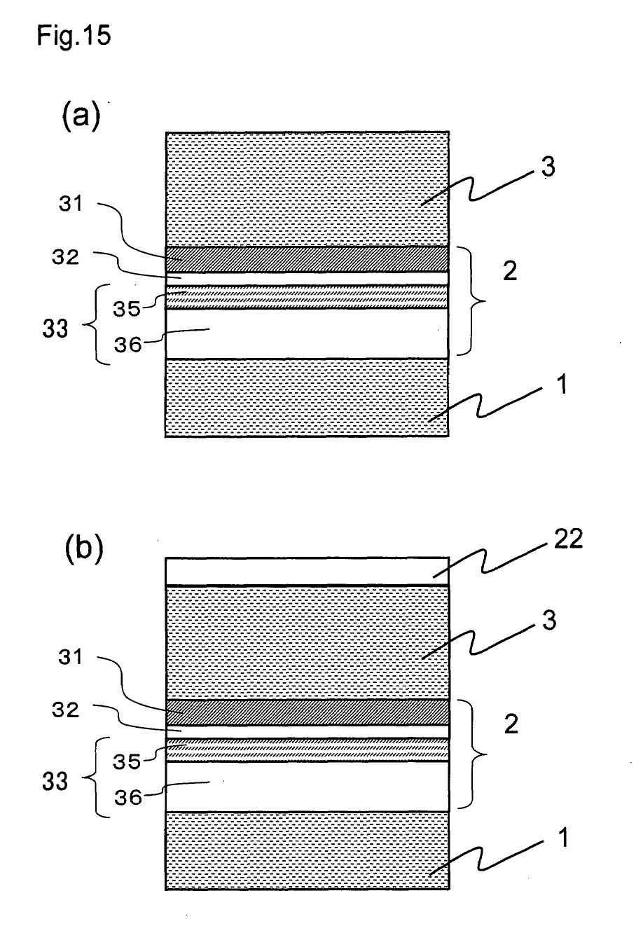

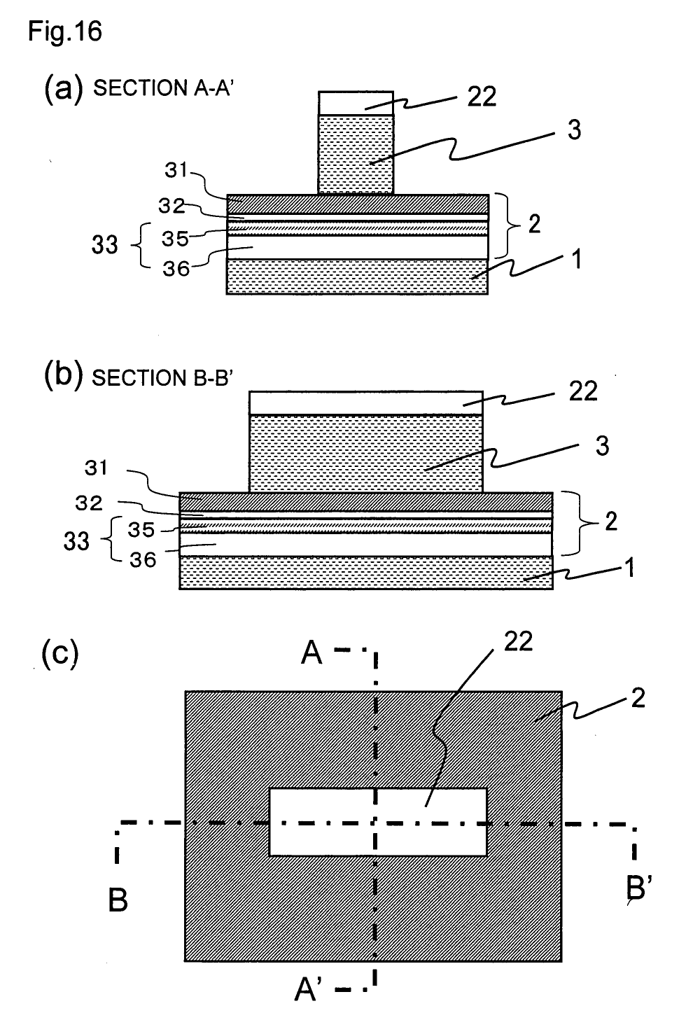

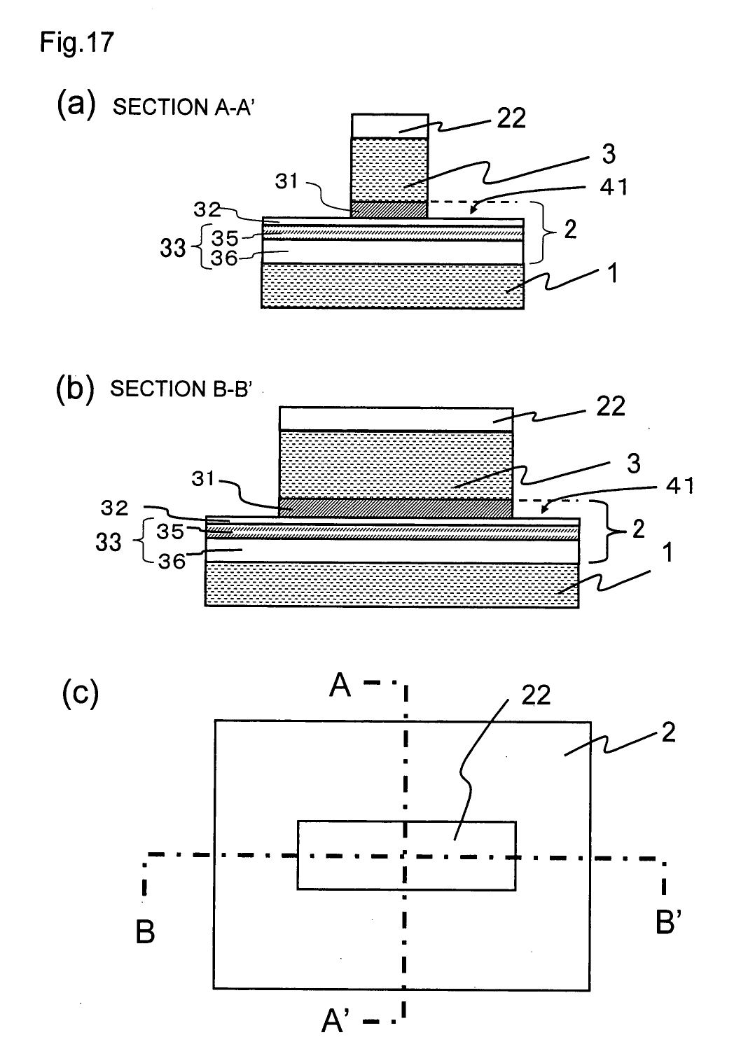

FIGS. 15(a) and 15(b), FIGS. 16(a), 16(b) and 16(c), FIGS. 17(a), 17(b) and 17(c), FIGS. 18(a), 18(b) and 18(c), FIGS. 19(a) and 19(b) are drawings corresponding to FIGS. 8(a) and 8(b), FIGS. 9(a), 9(b) and 9(c), FIGS. 10(a), 10(b) and 10(c), FIGS. 11(a), 11(b) and 11(c), FIGS. 12(a) and 12(b) in first embodiment, respectively.

When the upper buried insulating film 31 is composed of SiO₂ and the etch stopper layer 32 is composed of Si₃N₄, a configuration in which a part of the lower buried insulating film 33 has the buried high dielectric film 35 may also be formed if the etch stopper layer 32 is thin (typically 15 nm or less) and the electrostatic capacitance between the lower part of the gate electrode and the lower part of the semiconductor layer through the etch stopper layer is small. For example, the buried insulating film 33 may have a three-layer structure of thin SiO₂ (the thickness is typically 10 nm or less), the buried high dielectric film 35 and the buried insulating film 36 in the lower part composed of SiO₂ in descending order.

### Other Embodiments of the Invention

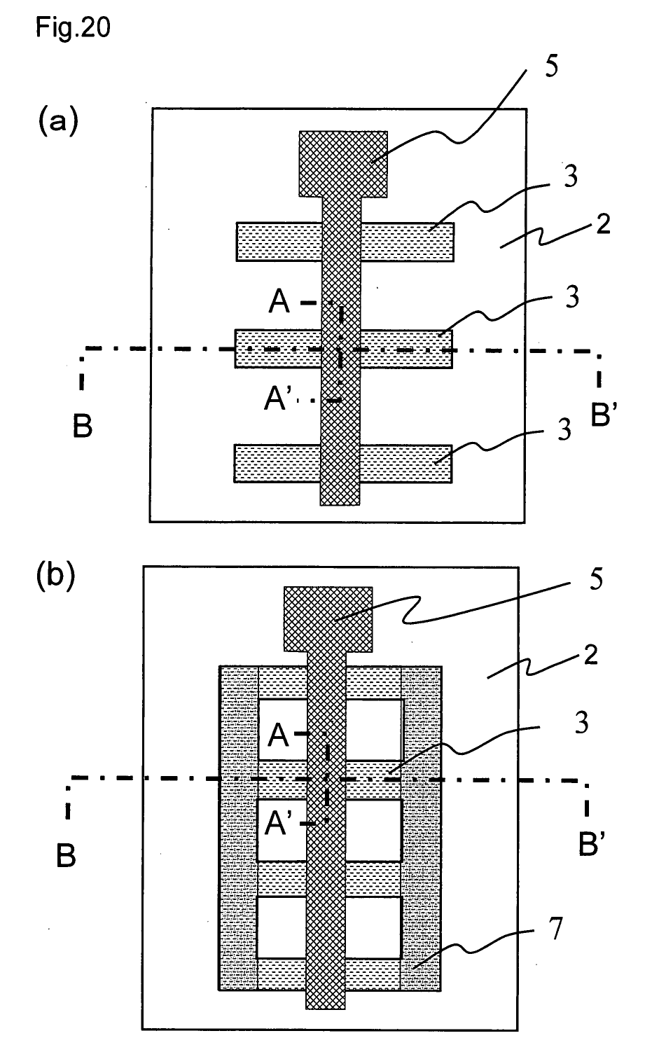

In each embodiment of the present invention, a case where an element region is a single rectangle has been shown, but each embodiment of the present invention may be applied to an element region having a multi-fin structure in which a plurality of Fins (semiconductor regions) are combined. In this case, section A-A′ of FIGS. 20(a) and 20(b) has a shape corresponding to section A-A of each embodiment of the present invention. Fins of FIGS. 20(a) and 20(b) are arranged such that the directions of channel currents passing through the Fins are mutually parallel. In the field effect transistor of FIG. 20(a), an independent gate electrode and source/drain region is provided for each Fin. In the field effect transistor of FIG. 20(b), a coupling region 7 extending in a direction orthogonally crossing the direction of the channel current and sandwiching and coupling the Fins is provided as a part of the source/drain region in addition to the Fins. The coupling region 7 consists of a semiconductor region extending in a direction orthogonally crossing the direction of the channel current. Furthermore, one gate electrode is formed so as to straddle the Fins coupled by the coupling region 7.

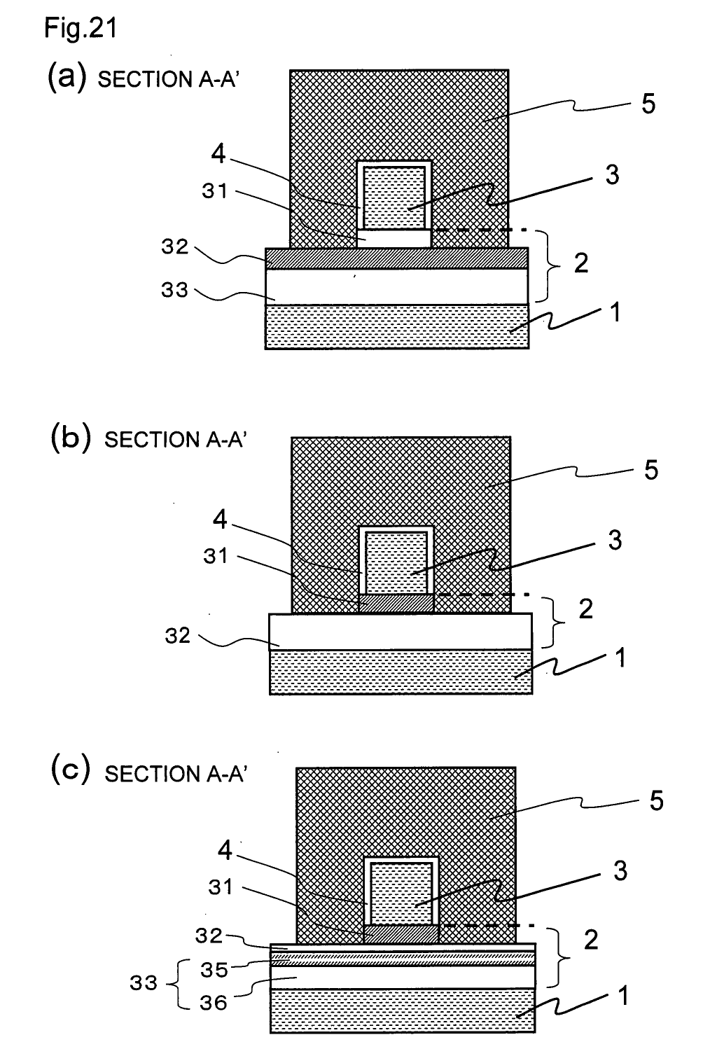

Each embodiment of the present invention may also be used for a trigate structure having no cap insulating film. A configuration formed in this case is shown in FIGS. 21(a), 21(b) and 21(c). FIGS. 21(a), 21(b) and 21(c) show sections corresponding to the sections of FIGS. 4(a), 11(a) and 18(a), respectively.

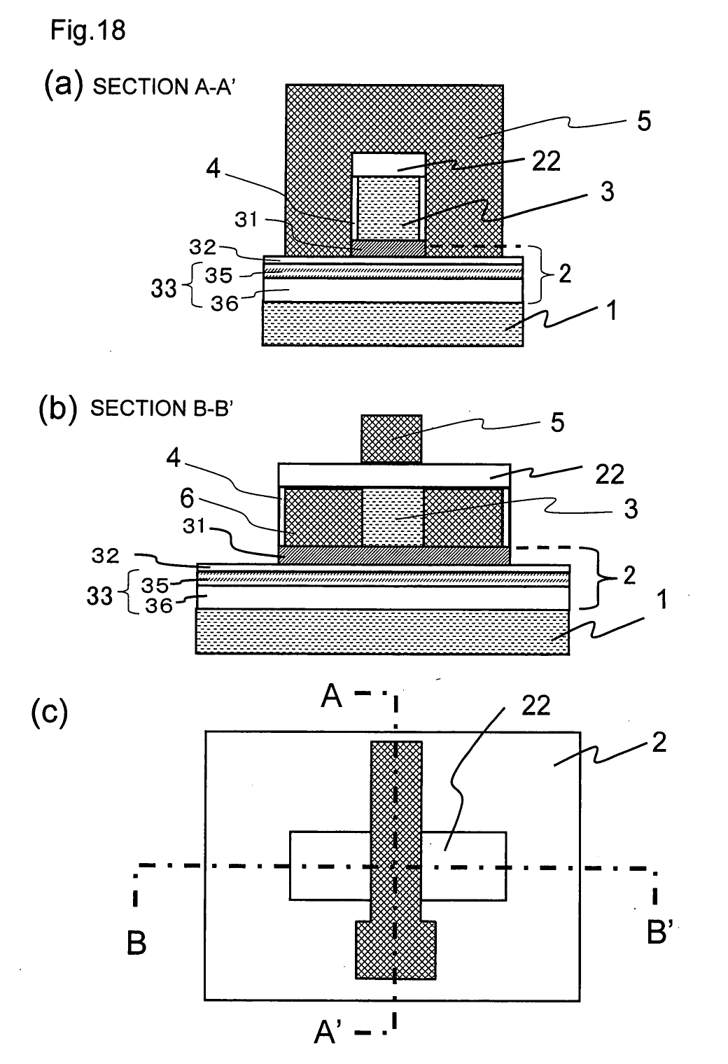

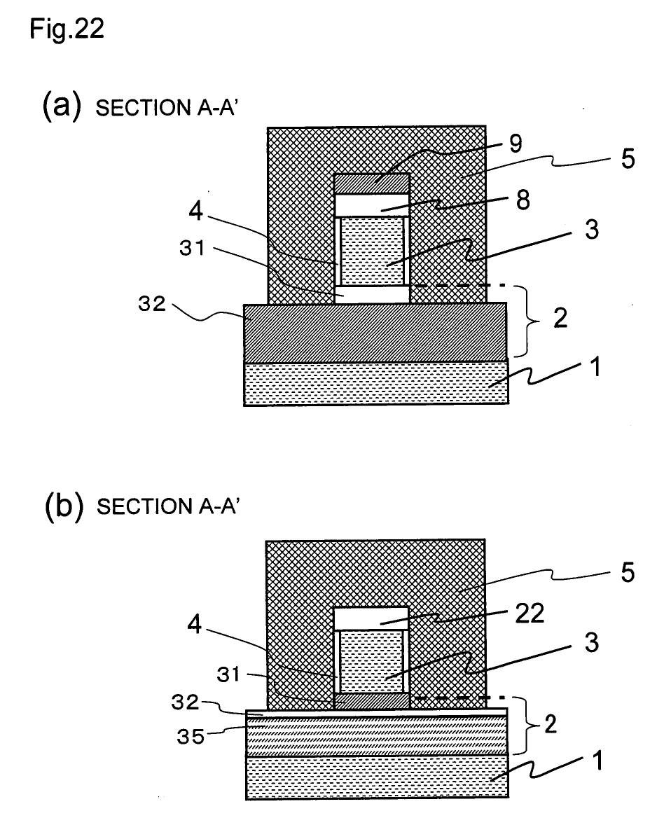

An example of a case where the buried insulating film 36 in the lower part is omitted is shown in FIGS. 22(a) and 22(b). FIGS. 22(a) and 22(b) show sections corresponding to the sections of FIGS. 4(a) and 18(a).

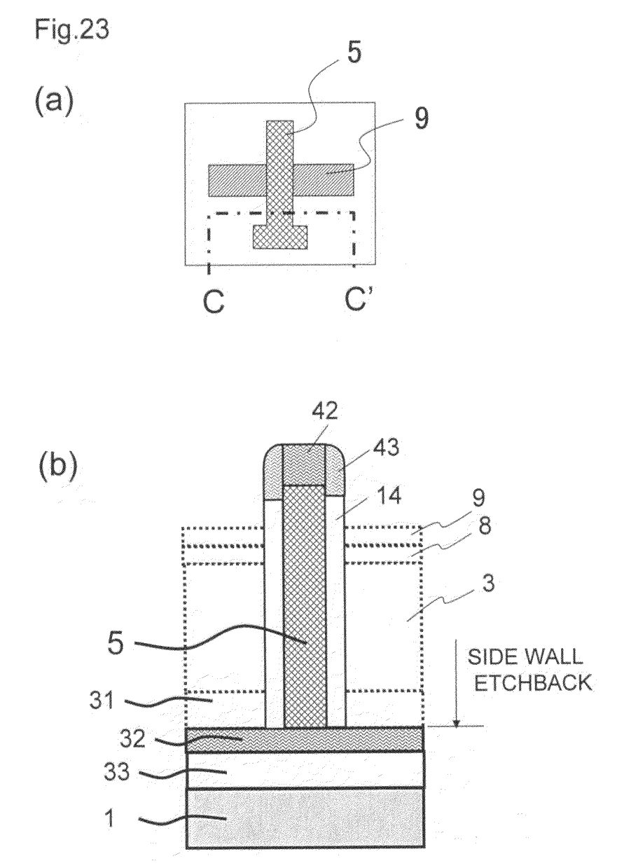

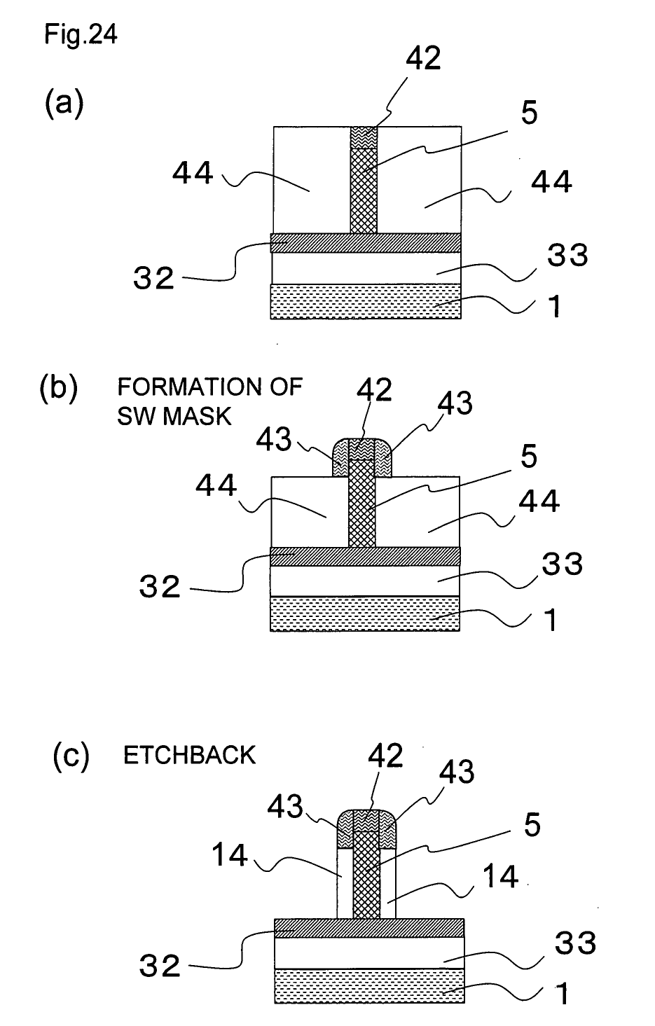

The etch stopper layer may be used as a stopper when forming a gate side wall. This is shown in FIGS. 23(a) and 23(b) and FIGS. 24(a), 24(b) and 24(c). Section C-C′ of top view 23(a) is shown in FIG. 23(b), and a side wall forming step depicted in order in the section of FIG. 23(b) is shown in FIGS. 24(a), 24(b) and 24(c). FIG. 24(a) corresponds to FIG. 4(c). The embodiment described here is an alteration of the first embodiment, the upper buried insulating film 31 is composed of SiO₂, the etch stopper layer 32 is composed of Si₃N₄, the lower buried insulating film 33 is composed of SiO₂, the first cap insulating film 8 is composed of SiO₂ and the second cap insulating film 9 is composed of Si₃N₄.

In the step in FIGS. 3(a) to 3(c) and FIGS. 4(a) to 4(c), a gate electrode material is deposited, a material of a gate cap film 42 (typically Si₃N₄, typical thickness: 20 to 50 nm) is then deposited, and the gate electrode material and the gate cap film material are patterned into a pattern of a gate electrode, whereby a configuration in which the gate cap film 42 is laminated on the gate electrode 5 as shown in FIG. 24(a) is formed. Subsequently, a side wall insulating film 44 (typically SiO₂, typical thickness: 500 nm) is thickly deposited in entirety, and the side wall insulating film 44 is flattened by CMP using the gate cap film 42 as a stopper (FIG. 24(a)).

Next, the upper part of the side wall insulating film 44 is selectively etched (the amount of etching is typically 20 to 50 nm), and a mask for a side wall (typically Si₃N₄, typical thickness: 10 to 50 nm) is thinly deposited in entirety, and etched back, whereby a mask 43 for a side wall is formed in the form of a side wall on the side surface of the exposed gate cap film 42 or the side surfaces of the exposed gate cap film 42 and gate electrode 5 (FIG. 24(b)).

Next, the side wall insulating film 44 is etched using the gate cap film 42 and the mask 43 for a side wall as a mask, whereby the side wall insulating film 44 is processed so as to be left on only the side surface of the gate electrode 5 and the gate side wall 14 is formed on the side surface of the gate electrode 5. At this time, at a portion distant from the gate electrode, the etch stopper layer 32 serves as a stopper when etching the side wall insulating film 44, and thus the lower buried insulating film and the like can be prevented from being etched in a step of etching the side wall insulating film 44.

If the gate side wall is formed by this method, the gate side wall can be formed on only the side surface of the gate electrode without forming the gate side wall on the side surface of the semiconductor layer 3 at a position distant from the gate electrode, thus making it possible to grow an epitaxial layer as a source/drain region on the side surface of the semiconductor layer after formation of the gate side wall or to form the side surface of the semiconductor layer into silicide after formation of the gate side wall.

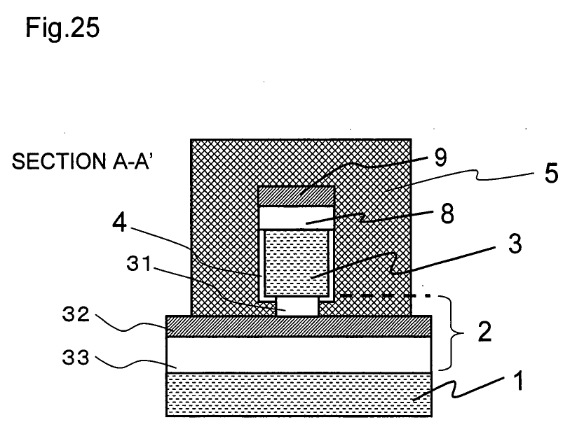

Each embodiment of the present invention may be applied to a configuration in which a part of the gate electrode partly extends to the lower part of the semiconductor layer (semiconductor region). A configuration corresponding to FIG. 4(a) is shown in FIG. 25. Namely, this FinFET is characteristic in that the width of the upper layer buried insulating layer in a direction orthogonally crossing the channel current direction is smaller than the width of the semiconductor layer in a direction orthogonally crossing the channel current direction, and a corner portion of the lower part of the semiconductor region is covered with the gate electrode via the insulating film. Thus, the DIBL (drain induced barrier loading) can be further suppressed as compared to a normal π gate FinFET, and therefore controllability of the gated electrode can be further improved and the off-current suppression effect in the present invention can be further strengthened.

In the present invention, a material having an etching rate lower than that of the first insulating film for etching under a predetermined condition used for etching of the upper buried insulating film 31 is selected for the material of the etch stopper layer as described in the first embodiment. Etching under a predetermined condition refers to an etching condition in which the etching rate for the upper buried insulating film 31 is higher than (typically equal to or higher than twice as large as) the etching rate for the etch stopper layer 32.

Normally, a condition used when etching SiO₂ by RIE meets the aforementioned predetermined condition when the etch stopper layer 32 is composed of SiO₂ or material having an atomic composition slightly changed from SiO₂ and the etch stopper layer is composed of Si₃N₄, since the etching rate for SiO₂ is higher than the etching rate for Si₃N₄.

Normally, a condition used when etching SiO₂ by RIE meets the aforementioned predetermined condition when the etch stopper layer 32 is composed of SiO₂ or material having an atomic composition slightly changed from SiO₂, since the etching rate for SiO₂ is higher than the etching rate for a material having a high dielectric constant, such as hafnium silicate, hafnium oxide, tantalum oxide or alumina.

Typically, when the upper buried insulating film 31 (or the lowermost layer of the upper buried insulating film 31 (layer contacting the etch stopper layer)) is composed of SiO₂ or a material having an atomic composition slightly changed from SiO₂, a condition in which the etching rate for SiO₂ is higher than the etching rate for Si₃N₄ may be selected as the aforementioned predetermined condition, and for the etch stopper layer, typically Si₃N₄ (or material having an atomic composition slightly changed from Si₃N₄) may be selected as a material having an etching rate lower than the etching rate for SiO₂ under this predetermined condition.

In the case of a condition in which the etching rate for SiO₂ is higher than the etching rate for Si₃N₄, the etching rate for a material having a high dielectric constant, such as hafnium silicate, hafnium oxide, tantalum oxide or alumina, is normally lower than the etching rate for SiO₂, and therefore a condition in which the etching rate for SiO₂ is higher than the etching rate for Si₃N₄ may be selected as the predetermined condition and a material having a high dielectric constant, such as hafnium silicate, hafnium oxide, tantalum oxide or alumina, may be used as a material of the etch stopper layer.

When the upper buried insulating film 33 (or the lowermost layer of the upper buried insulating film 33) is composed of a material containing nitrogen in a large amount (typically Si₃N₄ or a material having an atomic composition slightly changed from Si₃N₄), typically a condition in which the etching rate for Si₃N₄ is higher than the etching rate for SiO₂ may be selected as the aforementioned predetermined condition, and for the etch stopper layer, a material having a small content of nitrogen, typically SiO₂ (or a material having an atomic composition slightly changed from SiO₂) may be selected as a material having an etching rate lower than the etching rate for Si₃N₄ under this predetermined condition.

In each embodiment of the present invention, the etch stopper layer 32 may not be etched or may be partly etched in a step of forming the buried insulating layer digging portion 41.

In each embodiment of the present invention, the upper buried insulating film 31 may have a multilayer structure. For example, instead of the upper buried insulating film 31 of Si₃N₄, an upper part of the upper buried insulating film 31 contacting the semiconductor layer 3 may be formed with SiO₂ or SiON (typically 1.5 nm to 20 nm) and the lower part of the portion formed with SiO₂ or SiON may be formed with Si₃N₄ (the region of SiO₂ and the region of Si₃N₄ may have the atomic composition ratio and the types of constituent atoms deviated from a stoichiometric composition to a certain extent). If the upper part of the upper buried insulating film 31 contacting the semiconductor layer 3 is formed with SiO₂ or SiON, the interface level density between the semiconductor layer 3 and the upper buried insulating film 31 can be reduced as compared to a case where the semiconductor layer 3 exists on the Si₃N₄ film.

However, even when the upper buried insulating film 31 has a multilayer structure, a material constituting a portion contacting the etch stopper layer 32 is composed of a material (having an etching rate higher than, preferably equal to or higher than twice as large as, more preferably equal to or higher than 5 times as large as that of the etch stopper layer 32) capable of being etched selectively with respect to the etch stopper layer 32.

In each embodiment, the lower buried insulating film may consist of a plurality of layers. The support substrate may be an insulating film or a semiconductor layer. In each embodiment, when only a plurality of insulating films are laminated below the first insulating film, the layer just below the first insulating film is the etch stopper layer, the lowermost layer is the support substrate and the layer between the etch stopper layer and the support substrate is the lower buried insulating film.

The etch stopper layer may also be a multilayer. In this case, at least the uppermost layer (layer contacting the first insulating film) and lowermost layer of the etch stopper layer have resistance to etching for forming the buried insulating layer digging portion 41 (having an etching rate lower than (typically equal to or less than ½ of) that of a material to be etched for etching for forming the buried insulating layer digging portion 41).

However, the etch stopper layer is typically a single layer, and when the etch stopper layer is a multilayer, typically all layers forming the etch stopper layer have resistance to etching for forming the buried insulating layer digging portion 41.

The etch stopper layer is composed of a layer exposed by etching for forming the buried insulating layer digging portion 41 or a layer above this layer, or composed of a layer which may be exposed by etching for forming the buried insulating layer digging portion 41 due to variations in the process, or a layer above this layer.

In the present invention, when a material having a dielectric constant higher than that of SiO₂ is provided in a part of the insulating film provided below the semiconductor layer, namely any of the upper buried insulating film 31, the etch stopper layer 32 and the lower buried insulating film 33, or any of a part of the upper buried insulating film 31 situated below the semiconductor layer 3, a part of the etch stopper layer 32 situated below the semiconductor layer 3 and a part of the lower buried insulating film 33 situated below the semiconductor layer 3, electrostatic coupling between the lower surface or side surface of a region of the gate electrode protruding below the lower end of the semiconductor layer and an area close to the lower end of the semiconductor layer increases, controllability of an electric potential in an area close to the lower end of the semiconductor layer by the gate electrode is strengthened, and therefore the performance of the transistor is improved. Specifically, the subthreshold swing decreases and the off-current is reduced. The material having a dielectric constant higher than that of SiO₂ is typically Si₃N₄, or a material having a high dielectric constant, such as hafnium silicate, hafnium oxide or alumina. However, the composition ratio of atoms and constituent atoms in the materials described here may be deviated from a stoichiometric composition to a certain extent.

When a material having a dielectric constant higher than that of the upper buried insulating film is used for the etch stopper layer in the first embodiment of the present invention (in a specific example with the off-current shown in FIG. 7, the upper buried insulating film is composed of SiO₂ and the etch stopper layer is composed of Si₃N₄), the off-current reduction effect is great particularly in a region where Tdig is small as shown in FIG. 7. In this case, it can be said that Tdig is preferably 7.5 nm or greater, namely equal to or greater than ¼ of Wfin, since the off-current reaches a minimum vale and is stable when Tdig is 7.5 nm or greater, namely equal to or greater than ¼ of Wfin. In FIG. 7, the off-current no longer changes in a region where Tdig is 7.5 nm or greater, and therefore Tdig is preferably 7.5 nm or greater in the sense that variations in off-current are extremely small even if Tdig varies. But if Tdig is too large, a burden in terms of a process increases and a parasitic capacitance between the gate electrode and the support substrate and a parasitic capacitance between the gate electrode and the source/drain region increase, and therefore Tdig is preferably 15 nm or less, namely equal to or less than ½ of Wfin if considering a margin of a process.

In the second embodiment, Tdig reaches a minimum value and is stable at Tdig of 25 nm ( 5/7 of Wfin) or greater when a material having a dielectric constant higher than that of the etch stopper layer is used for the upper buried insulating film (in a specific example with the off-current shown in FIG. 14, the upper buried insulating film is composed of Si₃N₄ and the etch stopper layer is composed of SiO₂). As in the case of FIG. 7, if Tdig is too large, a burden in terms of a process increases and a parasitic capacitance between the gate electrode and the support substrate and a parasitic capacitance between the gate electrode and the source/drain region increase, and therefore Tdig is preferably 40 nm or less, namely equal to or less than 1.3 times as large as Wfin if considering a margin of a process.

If considering the results of FIGS. 7 and 14 together, it can be said that generally, Tdig is preferably 40 nm or less, namely equal to or less than 1.3 times as large as Wfin in the present invention.

For the SOI substrate having a multilayer buried insulating film, which is used in the present invention, a portion corresponding to the upper buried insulating film preferably has a thickness corresponding to the range of Tdig described in this specification. Namely, the thickness of the upper buried insulating film is 40 nm or less, or 15 nm or less, and the thickness of the upper buried insulating film is typically 7.5 nm or greater.

Since the uppermost buried insulating film of the SOI substrate having a multilayer buried insulating film, which is used in the present invention, corresponds to the upper buried insulating film or is a part of the upper buried insulating film, the thickness of the uppermost buried insulating film of the SOI substrate having a multilayer buried insulating film, which is used in the present invention, is 40 nm or less, or 15 nm or less.

The SOI substrate for use in the present invention is produced, for example, in a manner described below. First, an upper buried insulating film, an etch stopper layer and a lower buried insulating film are deposited in this order on a first silicon substrate by a film formation technique such as a CVD method or an ALD (atomic layer deposition) method. A second silicon substrate and the lower buried insulating film are bonded together by heating and pressing. The first silicon substrate is formed into a thin film to form a semiconductor layer. The second silicon substrate becomes a support substrate. A technique such as Smart Cut® or ELTRAN® may be used when the first silicon substrate is formed into a thin film to form a semiconductor layer. The lower buried insulating film, or the lower buried insulating film and the etch stopper layer, or the lower buried insulating film, the etch stopper layer and the upper buried insulating film may be formed on the second silicon substrate, and only a layer which is not formed on the second silicon substrate may be formed on the first silicon substrate. Incidentally, the materials of the upper buried insulating film, the etch stopper layer and the lower buried insulating film comply with a configuration used for the transistor described in the present invention.

Here, when the upper buried insulating film is composed of SiO₂, the upper buried insulating film may be formed by thermally oxidizing the first silicon substrate. When the upper buried insulating film is a multilayer film and its uppermost layer is a SiO₂ layer, the SiO₂ layer may be formed by thermally oxidizing the first silicon substrate. When the lower buried insulating film is composed of SiO₂, the lower buried insulating film may be formed by thermally oxidizing the second silicon substrate. When the lower buried insulating film is a multilayer film and its lowermost layer is a SiO₂ layer, the SiO₂ layer may be formed by thermally oxidizing the second silicon substrate.

For the substrate having a plurality of insulating films (the first insulating film of one or more layers, the etch stopper layer and the lower buried insulating film of one or more layers) laminated in the lower part of the semiconductor layer as described above, for example, a substrate in which the uppermost layer is a semiconductor layer and below the layer, SiO₂ layers and Si₃N₄ layers are alternately laminated may be used.

Typically, below the semiconductor layer, a SiO₂ layer corresponding to the first insulating film and a Si₃N₄ layer corresponding to the etch stopper layer are provided and below the layer, a SiO₂ layer corresponding to the lower buried insulating film is provided. Alternatively, below the semiconductor layer, a Si₃N₄ layer corresponding to the first insulating film and a SiO₂ layer corresponding to the etch stopper layer are provided. A plurality of insulating films corresponding to various kinds of embodiments described in this specification are provided below the semiconductor layer.

The lower part of a plurality of insulating films provided below the semiconductor layer is held by a support substrate composed of a semiconductor (typically silicon) or an insulator (sapphire, quarts, etc.).

The semiconductor layer is typically a silicon layer, but it may be a layer of a semiconductor other than silicon, such as SiGe. The semiconductor layer may consist of different types of semiconductor layers laminated.

The buried insulating film is provided so as to extend typically all over a wafer or extend all over at least a certain area on which a plurality of transistors are provided.

Layers having the same function (any of the upper buried insulating film, the etch stopper layer and the lower buried insulating film) may be formed on the first silicon substrate and second silicon substrate, and bonded to each other. For example, the upper buried insulating film, the etch stopper layer and the lower buried insulating film may be formed in this order on the first silicon substrate, the lower buried insulating film may be formed on the second silicon substrate, and the lower buried insulating film on the first silicon substrate and the lower buried insulating film on the second silicon substrate may be bonded to each other.

The present invention is normally applied to a very small transistor having a gate length of 180 nm or less. The typical gate length is 25 nm to 90 nm.

The fin width Wfin (width of the semiconductor layer 3 in the lateral direction on the sheet plane of FIG. 5(a)) is normally 5 nm to 50 nm, typically 10 nm to 35 nm. However, in a very small transistor having a gate length of less than 50 nm, the fin width Wfin may be 5 nm or less. The height of the semiconductor layer Hfin is typically 15 nm to 70 nm.

The gate electrode is composed of polysilicon, or a conductive material such as a metal or a metal silicide.

A channel formation region (portion covered with the gate electrode) of the semiconductor layer forming a Fin region may or may not be doped with an impurity. When the gate electrode is composed of polysilicon, normally a p type impurity is introduced for an n channel transistor and an n type impurity is introduced for a p channel transistor. In the source/drain region is introduced an n type impurity for an n channel transistor or a p type impurity for a p channel transistor in a high concentration (normally 10¹⁹ cm⁻³ or higher, typically 10¹⁹ cm⁻³ or higher). The n type impurity is typically a donor impurity such as As, P or Sb, and the p type impurity is typically an acceptor impurity such as In, B or Al.

The channel formation region (portion of the semiconductor layer sandwiched by the source/drain region and covered with the gate electrode) may be subjected to low-concentration channel ion implantation, or may not be subjected to channel ion implantation. The channel formation region adjacent to the source/drain region of a first conductivity type may have a hollow region into which an impurity of a second conductivity type is introduced over a certain width.

In the drawings of this specification, a case where the sections of the semiconductor layer, various kinds of insulating films and the second cap insulating film are rectangular has been shown as a typical example, but actually, the section may have a shape deviated from a rectangle due to influences of production steps such as an etching step and a thermal oxidization step. The corner portion of the semiconductor layer may be rounded due to the thermal oxidization step of, for example, sacrificial oxidization, gate oxidization and the like. The side surface of each component such as the semiconductor layer or the upper buried insulating film may be tapered or gently curved due to influences of, for example, an etching step such as RIE.

Incidentally, the atomic composition ratio in a material composed of a plurality of elements, for example a material such as SiO₂ or Si₃N₄, which is used as a component of the field effect transistor in each embodiment may be deviated from a stoichiometric composition to a certain extent within the boundary of obtaining the effect of the present invention. Elements that are not contained in a stoichiometric composition may be mixed to a certain extent within the boundary of obtaining the effect of the present invention.

The thickness of the etch stopper layer is not specifically limited, but it is normally about 5 nm to 150 nm. However, the thickness of the etch stopper layer preferably exceeds a minimum thickness given by the following formula and allowing an effect to be obtained as an etch stopper. (thickness of upper buried insulating film)×(1+x)/(1−x)×(etching rate of etch stopper layer)/(etching rate of upper buried insulating film).

However, x represents a ratio of the thickness of the insulating film to a specified value of the amount of variations in etching rate. Namely, x is 0.2 when the amount of variations is 20%. The product of (1+x)/(1−x) represents the amount of etching in a portion where the etching rate is the highest when the entire upper buried insulating film is etched in a portion where the etching rate is lowest. The typical value of x is 0.2.

Incidentally, the “base” refers to any flat surface parallel (horizontal) to the substrate in the present invention.

1. A field effect transistor,
wherein a first insulating film composed of one or more layers and a semiconductor region provided on the first insulating film are provided so as to protrude upward with respect to the flat surface of a base,
the field effect transistor comprises:
a gate electrode provided so as to straddle the semiconductor region and the first insulating film from the upper part of the semiconductor region;
a gate insulating film provided between the gate electrode and at least the side surface of the semiconductor region; and
a source/drain region provided in the semiconductor region so as to sandwich the gate electrode,
wherein a channel is formed at least on the side surface of the semiconductor region and
the first insulating film is provided on an etch stopper layer composed of a material having an etching rate lower than at least the lowermost layer of the first insulating film for etching under a predetermined condition.

2. A field effect transistor comprising:
a protrusive semiconductor region;
a gate electrode provided so as to extend from the upper part of the semiconductor region to the position below the lower end of the semiconductor region;
a first insulating film provided below the semiconductor region so as to be sandwiched by the gate electrode;
a gate insulating film provided between the gate electrode and at least the side surface of the semiconductor region; and
a source/drain region provided in the semiconductor region so as to sandwich the gate electrode, and
wherein a channel is formed at least on the side surface of the semiconductor region and
the first insulating film is provided on an etch stopper layer composed of a material having an etching rate lower than at least the lowermost layer of the first insulating film for etching under a predetermined condition.

3. The field effect transistor according to claim 1 or 2, wherein the field effect transistor comprises a layer composed of a material having a dielectric constant higher than that of SiO₂ below the semiconductor region.

4. The field effect transistor according to claim 1 or 2, wherein the first insulating film comprises a layer composed of a material having a dielectric constant higher than that of SiO₂ at least on the etch stopper layer side.

5. The field effect transistor according to claim 4, wherein the etch stopper layer comprises a SiO₂ layer at least on the first insulating film side.

6. The field effect transistor according to claim 4, wherein the field effect transistor comprises a layer composed of a material having a dielectric constant higher than that of SiO₂ and a SiO₂ layer in descending order below the etch stopper layer.

7. The field effect transistor according to claim 3, wherein the first insulating film comprises a SiO₂ layer on the etch stopper layer side.

8. The field effect transistor according to claim 7, wherein the etch stopper layer comprises a layer composed of a material having a dielectric constant higher than that of SiO₂ at least on the first insulating film side.

9. The field effect transistor according to claim 7, wherein the field effect transistor comprises a SiO₂ layer below the etch stopper layer.

10. The field effect transistor according to claim 3, wherein the material having a dielectric constant higher than that of SiO₂ is Si₃N₄.

11. The field effect transistor according to claim 1 or 2, wherein the field effect transistor comprises at least one cap insulating film between the upper surface of the semiconductor region and the gate electrode.

12. The field effect transistor according to claim 11, wherein the cap insulating film comprises a layer composed of a material same as that of the etch stopper layer.

13. The field effect transistor according to claim 12, wherein the uppermost layer of the cap insulating film is a layer composed of a material same as that of the etch stopper layer.

14. The field effect transistor according to claim 1 or 2, wherein the thickness of the first insulating film is 40 nm or less.

15. The field effect transistor according to claim 1 or 2, wherein the thickness of the first insulating film is 15 nm or less.

16. The field effect transistor according to claim 1 or 2, wherein the thickness of the first insulating film is in a range of 7.5 nm to 40 nm.

17. The field effect transistor according to claim 1 or 2, wherein the thickness of the first insulating film is equal to or less than 1.3 times as large as a width in a direction orthogonally crossing a direction of a channel current in the semiconductor region.

18. The field effect transistor according to claim 1 or 2, wherein the thickness of the first insulating film is equal to or less than ½ times as large as a width in a direction orthogonally crossing a direction of a channel current in the semiconductor region.

19. The field effect transistor according to claim 1 or 2, wherein the thickness of the first insulating film is in a range of ¼ to 1.3 times as large as a width in a direction orthogonally crossing a direction of a channel current in the semiconductor region.

20. A field effect transistor comprising:
a SiO₂ region formed on a Si₃N₄ layer by etching under a condition bringing about an etching rate higher than Si₃N₄;
a semiconductor region provided on the SiO₂ region;
a gate electrode provided so as to straddle the semiconductor region and the SiO₂ region from the upper part of the semiconductor region;
a gate insulating film provided between the gate electrode and at least the side surface of the semiconductor region; and
a source/drain region provided in the semiconductor region so as to sandwich the gate electrode,
wherein a channel is formed on the side surface of the semiconductor region.

21. The field effect transistor according to claim 20, wherein the field effect transistor comprises a cap insulating film between the upper surface of the semiconductor region and the gate electrode.

22. The field effect transistor according to claim 21, wherein the field effect transistor comprises a Si₃N₄ layer as the cap insulating film.

23. A field effect transistor comprising:
a Si₃N₄ region formed on a SiO₂ layer by etching under a condition bringing about an etching rate higher than SiO₂;
a semiconductor region provided on the Si₃N₄ region;
a gate electrode provided so as to straddle the semiconductor region and the Si₃N₄ region from the upper part of the semiconductor region;
a gate insulating film provided between the gate electrode and at least the side surface of the semiconductor region; and
a source/drain region provided in the semiconductor region so as to sandwich the gate electrode,
wherein a channel is formed on the side surface of the semiconductor region.

24. The field effect transistor according to claim 23, wherein the field effect transistor comprises a Si₃N₄ layer and a SiO₂ layer in descending order below the SiO₂ layer.

25. The field effect transistor according to claim 23 or 24, wherein the field effect transistor comprises a SiO₂ layer as a cap insulating film between the upper surface of the semiconductor region and the gate electrode.

26. The field effect transistor according to claim 25, further comprising a Si₃N₄ layer as the cap insulating film below the SiO₂ layer.

27. The field effect transistor according to any one of claims 1, 2, 20 or 23, wherein the etching is reactive ion etching.

28. The field effect transistor according to claim 1 or 2, wherein the width in a direction orthogonally crossing a channel current in the first insulating film is smaller than a width in a direction orthogonally crossing a channel current in the semiconductor region.

29. The field effect transistor according to any one of claims 1, 2, 20 or 23, wherein a plurality of semiconductor regions protruding upward from the surface of the base are arranged so that the directions of channel currents passing through the insides of the semiconductor regions are mutually parallel.

30. A substrate for a field effect transistor comprising a semiconductor layer and layers having SiO₂ layers and Si₃N₄ layers laminated alternately below the semiconductor layer.

31. A substrate for a field effect transistor comprising a semiconductor layer, a Si₃N₄ layer and a SiO₂ layer in descending order.

32. A substrate for a field effect transistor comprising a semiconductor layer, a SiO₂ layer, a Si₃N₄ layer and a SiO₂ layer in descending order.

33. A substrate for a field effect transistor comprising a semiconductor layer, a Si₃N₄ layer, a SiO₂ layer, a Si₃N₄ layer and a SiO₂ layer in descending order.

34. A substrate for a field effect transistor comprising in descending order a semiconductor layer, a first insulating film layer and an etch stopper layer composed of a material having an etching rate lower than that of the first insulating film layer for etching under a predetermined condition.

35. The substrate for a field effect transistor according to claim 34, wherein the etching is reactive ion etching.

36. The substrate for a field effect transistor according to claim 34 or 35, wherein the thickness of the first insulating film layer is 30 nm or less.

37. The substrate for a field effect transistor according to claim 34 or 35, wherein the thickness of the first insulating film layer is 15 nm or less.

38. The substrate for a field effect transistor according to claim 34 or 35, wherein the thickness of the first insulating film layer is in a range of 7.5 nm to 30 nm.

39. The substrate for a field effect transistor according to claim 38, wherein the first insulating film layer is a SiO₂ layer.

40. The substrate for a field effect transistor according to any one of claims 30 to 35, wherein the semiconductor layer is a silicon layer.

41. The substrate for a field effect transistor according to any one of claims 30 to 35, wherein the semiconductor layer is a monocrystalline silicon layer.

42. A method for production of a field effect transistor in which at least one first insulating film and a semiconductor region provided on the first insulating film are provided so as to protrude upward with respect to the flat surface of a base, the field effect transistor has a gate electrode provided so as to straddle the first insulating film and the semiconductor region from the upper part of the semiconductor region, and the field effect transistor in which a channel is formed at least on the side surface of the semiconductor region, comprising the steps of:
(a) etching a substrate having at least a semiconductor layer, a first insulating film layer consisting of one or more layers and an etch stopper layer in descending order, and forming a semiconductor region protruding on the first insulating film layer; and
(b) etching a portion of the first insulating film layer other than the portion provided with the semiconductor region until the etching reaches the etch stopper layer under a condition such that the etching rate of at least the lowermost layer of the first insulating film layer is higher than the etching rate of the etch stopper layer, and providing below the semiconductor region the first insulating film protruding upward from the etch stopper layer.

43. The method for production of a field effect transistor according to claim 42, further comprising the steps of:
forming a gate insulating film on the side surface of the semiconductor region;
forming a gate electrode by depositing a gate electrode material and patterning the gate electrode material deposition film; and
introducing an impurity on both sides of the semiconductor region sandwiching the gate electrode to form a source/drain region.

44. The method for production of a field effect transistor according to claim 43, wherein the step of forming the gate electrode comprises a step of providing a gate side wall.

45. The method for production of a field effect transistor according to any one of claims 42 to 44, wherein in the step (b) of providing the first insulating film, etching is carried out under a condition such that the etching rate of the lowermost layer of the first insulating film layer is equal to or greater than twice as large as the etching rate of the etch stopper layer.

46. The method for production of a field effect transistor according to any one of claims 42 to 44, wherein in the step (b) of providing the first insulating film, etching is carried out under a condition such that the etching rate of the lowermost layer of the first insulating film layer is equal to or greater than 5 times as large as the etching rate of the etch stopper layer.

47. The method for production of a field effect transistor according to claim 44, wherein the step of providing the gate side wall are steps of depositing a gate side wall material on the entire surface, and then carrying out etch-back under a condition such that the etching rate of the gate side wall material is higher than the etching rate of the etch stopper layer.

48. The method for production of a field effect transistor according to any one of claims 42, 43, 44 or 47, wherein in the step (b) of providing the first insulating film, the etching is reactive ion etching

49. The method for production of a field effect transistor according to any one of claim 42, 43, 44 or 47, wherein in the step (a) of forming the semiconductor region, a plurality of semiconductor regions are arranged so that the directions of channel currents passing through the semiconductor regions are mutually parallel.
